(19) United States
(12) Patent Application Publication
(10) Pub. No.: US 2025/0323151 A1
(43) Pub. Date: Oct. 16, 2025

(54) MANAGING CONTACT STRUCTURES IN SEMICONDUCTOR DEVICES

(71) Applicant: Yangtze Memory Technologies Co., Ltd., Wuhan, Hubei (CN)

(72) Inventors: Zhong ZHANG, Wuhan (CN); Yonggang YANG, Wuhan (CN); Yang CHEN, Wuhan (CN); Kun ZHANG, Wuhan (CN); Wenxi ZHOU, Wuhan (CN)

(21) Appl. No.: 18/783,253

(22) Filed: Jul. 24, 2024

Related U.S. Application Data
(63) Continuation of application No. PCT/CN2024/087437, filed on Apr. 12, 2024.

(51) Int. Cl. H01L 23/528; H01L 21/768; H01L 27/088; H01L 29/40; H01L 29/423; H01L 29/78; H10B 61/00; H10B 63/10

(52) U.S. Cl. CPC H01L 23/528; H01L 21/76877; H10D 30/63; H10D 64/01; H10D 64/512; H10D 84/83; H10B 61/00; H10B 63/10

(57) ABSTRACT

The present disclosure relates to methods, devices, systems, and techniques for managing contact structures in semiconductor devices. An example semiconductor device includes a first stack of conductive layers and isolating layers alternating with each other along a first direction and a second stack of dielectric layers and isolating layers alternating with each other along the first direction. A connection region of the semiconductor device is adjacent to an array region of the semiconductor device in a second direction perpendicular to the first direction. The second stack is in the connection region and is connected to the first stack. The semiconductor device further includes contact structures extending through at least a part of the second stack along the first direction.

### CROSS-REFERENCE TO RELATED APPLICATIONS

This application is a continuation of International Application No. PCT/CN2024/087437, filed on Apr. 12, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first stack of conductive layers and isolating layers alternating with each other along a first direction and a second stack of dielectric layers and isolating layers alternating with each other along the first direction. A connection region of the semiconductor device is adjacent to an array region of the semiconductor device in a second direction perpendicular to the first direction. The second stack is in the connection region and is connected to the first stack. The semiconductor device further includes contact structures extending through at least a part of the second stack along the first direction. A contact structure of the contact structures includes a body extending along the first direction and a bottom layer extending along a third direction perpendicular to the first direction and the second direction. A first conductive layer of the first stack is coupled to the bottom layer of the contact structure. The first conductive layer has an end in contact with the bottom layer of the contact structure. A second conductive layer of the first stack has an end in contact with a dielectric layer of the second stack. The end of the first conductive layer is between the end of the second conductive layer and the body of the contact structure along the third direction.

In some implementations, the semiconductor device further includes a gate line structure extending through the first stack along the first direction. The end of the first conductive layer is farther away from the gate line structure along the third direction than the end of the second conductive layer.

In some implementations, the first conductive layer is in contact with a first liner layer and a second liner layer at a position of the end of the second conductive layer along the third direction. The first liner layer is between the first conductive layer and a first isolating layer adjacent to the first conductive layer. The second liner layer is between the first conductive layer and a second isolating layer adjacent to the first conductive layer.

In some implementations, the first liner layer includes a high-K dielectric material, and the second liner layer includes the high-K dielectric material.

In some implementations, the bottom layer of the contact structure includes a first portion and a second portion. The first portion is between the first conductive layer and the first isolating layer along the first direction. The first portion is in contact with the first liner layer along the third direction. The second portion is between the first conductive layer and the second isolating layer along the first direction. The second portion is in contact with the second liner layer along the third direction.

In some implementations, the contact structure further includes an outer layer surrounding the body. The outer layer and the body are connected to the bottom layer of the contact structure. The outer layer includes a first conductive material. The bottom layer includes the first conductive material. The body includes a second conductive material. The conductive layers include the second conductive material.

In some implementations, a size of the bottom layer of the contact structure along the first direction at a first position is smaller than a size of the bottom layer of the contact structure along the first direction at a second position. The first position and the second position are along the third direction between the first conductive layer and the contact structure. The first position is closer to the end of the first conductive layer than the second position along the third direction.

In some implementations, the contact structure is surrounded by a contact spacer that includes a dielectric material.

Another aspect of the present disclosure features a method of forming a semiconductor device. The method includes forming a semiconductor structure including a first stack of conductive layers and isolating layers alternating with each other along a first direction and a second stack of dielectric layers and isolating layers alternating with each other along the first direction. The semiconductor structure includes an array region and a connection region adjacent to the array region in a second direction perpendicular to the first direction. The second stack is in the connection region and is connected to the first stack. The method further includes forming contact structures that extend through at least a part of the second stack along the first direction. Forming the contact structures includes forming a contact structure including a body extending along the first direction and a bottom layer extending along a third direction perpendicular to the first direction and the second direction. The bottom layer of the contact structure is coupled to a first conductive layer of the first stack. The first conductive layer has an end in contact with the bottom layer of the contact structure. A second conductive layer of the first stack has an end in contact with a dielectric layer of the second stack. The end of the first conductive layer is between the end of the second conductive layer and the body of the contact structure along the third direction.

In some implementations, the method includes: providing a stack of sacrificial layers and isolating layers alternating with each other along the first direction; forming a contact hole in the connection region, where the contact hole extends into the stack along the first direction and reaches a first sacrificial layer of the sacrificial layers; forming a first space in the first sacrificial layer by removing a portion of the first sacrificial layer; and forming a filling body in the contact hole and a filling layer in the first space by filling the contact hole and the first space with a first filling material, where the filling body is connected to the filling layer, and the filling layer extends along the third direction.

In some implementations, forming the semiconductor structure includes forming a gate line slit extending through the first stack along the first direction. The gate line slit includes a first segment in the array region and a second segment in the connection region. An isolation structure is between the first segment and the second segment along the second direction.

In some implementations, forming the first space in the first sacrificial layer by removing the portion of the first sacrificial layer includes: etching off a first portion of the first sacrificial layer and portions of two isolating layers adjacent to the first sacrificial layer during a first time period of an etching process; and etching off a second portion of the first sacrificial layer during a second time period of the etching process. A size of the first space along the first direction at a first position is smaller than a size of the first space along the first direction at a second position. The first position and the second position are arranged along the third direction between the gate line slit and the contact hole. The first position is closer to the gate line slit than the second position along the third direction.

In some implementations, forming the semiconductor structure includes forming tunnels in the connection region by filling an etching solution through the second segment of the gate line slit to remove portions of the sacrificial layers in the connection region. The tunnels are between the isolating layers. The second segment of the gate line slit extends through the tunnels along the first direction. The sacrificial layers include the first sacrificial layer and second sacrificial layers. The tunnels include a first tunnel that is aligned with the filling layer and the first sacrificial layer along the third direction and second tunnels that are aligned with the second sacrificial layers along the third direction. The first tunnel exposes the filling layer. The second tunnels expose ends of remaining portions of the second sacrificial layers.

In some implementations, forming the semiconductor structure includes enlarging the first tunnel along the third direction by removing a portion of the filling layer. The enlarged first tunnel exposes an end of a remaining portion of the filling layer. The end of the remaining portion of the filling layer is farther away from the second segment of the gate line slit along the third direction than the ends of the remaining portions of the second sacrificial layers.

In some implementations, forming the semiconductor structure includes: filling the second segment of the gate line slit and the tunnels with a second filling material; removing the sacrificial layers in the array region by filling an etching solution through the first segment of the gate line slit; removing the second filling material in the second segment of the gate line slit and the tunnels; and forming the first stack by forming the conductive layers of the first stack between the isolating layers. The conductive layers are formed by depositing at least a high-K dielectric material and a first conductive material through the first segment of the gate line slit and the second segment of the gate line slit. The conductive layers include a first conductive layer surrounded by a liner layer. The liner layer includes a first segment, a second segment, and a third segment that are connected. The first conductive layer is between a first isolating layer and a second isolating layer that are adjacent to the first conductive layer. The first segment of the liner layer is between the first conductive layer and the first isolating layer along the first direction. The second segment of the liner layer is between the first conductive layer and the second isolating layer along the first direction. The third segment of the liner layer is between the first conductive layer and the filling layer along the third direction.

In some implementations, forming the semiconductor structure includes: removing the first filling material in the contact hole; forming a second space aligned with the first sacrificial layer along the third direction by removing the first filling material in the filling layer; removing the third segment of the liner layer to expose the first conductive layer; forming a first recess between the first conductive layer and the first isolating layer by removing a portion of the first segment of the liner layer that was connected to the third segment of the liner layer; and forming a second recess between the first conductive layer and the second isolating layer by removing a portion of the second segment of the liner layer that was connected to the third segment of the liner layer.

In some implementations, forming the contact structure includes forming an outer layer of the contact structure and the bottom layer of the contact structure by depositing a second conductive material through the contact hole. The outer layer is in contact with an inner surface of the contact hole. The bottom layer of the contact structure is in the second space aligned with the first sacrificial layer and is in contact with the first conducive layer. The bottom layer of the contact structure includes a first portion in the first recess and a second portion in the second recess. Forming the contact structure further includes forming a body of the contact structure by depositing the first conductive material into the contact hole, where the body is surrounded by the outer layer.

A further aspect of the present disclosure features a memory system. The memory system includes a memory device and a memory controller coupled to the memory device and configured to control the memory device. The memory device includes a first stack of conductive layers and isolating layers alternating with each other along a first direction and a second stack of dielectric layers and isolating layers alternating with each other along the first direction. A connection region of the memory device is adjacent to an array region of the memory device in a second direction perpendicular to the first direction. The second stack is in the connection region and is connected to the first stack. The memory device further includes contact structures extending through at least a part of the second stack along the first direction. A contact structure of the contact structures includes a body extending along the first direction and a bottom layer extending along a third direction perpendicular to the first direction and the second direction. A first conductive layer of the first stack is coupled to the bottom layer of the contact structure. The first conductive layer has an end in contact with the bottom layer of the contact structure. A second conductive layer of the first stack has an end in contact with a dielectric layer of the second stack. The end of the first conductive layer is between the end of the second conductive layer and the body of the contact structure along the third direction.

In some implementations, the first conductive layer is in contact with a first liner layer and a second liner layer at a position of the end of the second conductive layer along the third direction. The first liner layer is between the first conductive layer and a first isolating layer adjacent to the first conductive layer. The second liner layer is between the first conductive layer and a second isolating layer adjacent to the first conductive layer. The bottom layer of the contact structure includes a first portion and a second portion. The first portion is between the first conductive layer and the first isolating layer along the first direction. The first portion is in contact with the first liner layer along the third direction. The second portion is between the first conductive layer and the second isolating layer along the first direction. The second portion is in contact with the second liner layer along the third direction.

In some implementations, a size of the bottom layer of the contact structure along the first direction at a first position is smaller than a size of the bottom layer of the contact structure along the first direction at a second position. The first position and the second position are arranged along the third direction between the first conductive layer and the contact structure. The first position is closer to the first conductive layer than the second position along the third direction.

### BRIEF DESCRIPTION OF DRAWINGS

FIGS. 1A-1B illustrate an example semiconductor device.

FIGS. 2A-2Z illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. For example, the memory device can have multiple decks, and each deck can have multiple layers. The large number of layers and the high aspect ratio of such memory devices may bring challenges to the manufacturing process. For example, stress issues can become more severe and cause X-Y bow problem in conductive layer filling. In other words, the conductive layers may bend during fabrication of the memory device. In another example, a connection between a conductive layer and a contact structure may cause a loss of a high-K dielectric material of a liner layer between the conductive layer and adjacent isolating layers. That is, the uniformity of a structure of the conductive layer is affected, thereby reducing a breakdown voltage between the conductive layer and adjacent conductive layers. Therefore, contact structures and fabrication methods that can solve the aforementioned issues are desirable.

In one or more implementations of the present disclosure, an example semiconductor device is provided. The semiconductor device includes a first stack of alternating conductive layers and isolating layers and a second stack of alternating dielectric layers and isolating layers. The semiconductor device further includes a contact structure extending through at least a part of the second stack along a vertical direction. The contact structure includes a body extending along the vertical direction and a bottom layer extending along a horizontal direction. A first conductive layer of the first stack is coupled to the bottom layer of the contact structure. The first conductive layer has an end in contact with the bottom layer of the contact structure. A second conductive layer of the first stack has an end in contact with a dielectric layer of the second stack. The end of the first conductive layer is between the end of the second conductive layer and the body of the contact structure along the horizontal direction.

Implementations of the present disclosure can provide one or more of the following technical advantages and/or benefits. First, in the example semiconductor device described above, the first conductive layer's end and the second conductive layer's end can offset along the horizontal direction. Thus, the end of the first conductive layer can be protected by adjacent isolating layers along the vertical direction, thereby mitigating or resolving the breakdown voltage issue caused by the high-K dielectric material loss. Second, thicker isolating layers may not be required, which allows a size of the semiconductor device to be smaller. Third, in some implementations, a center of the bottom layer of the contact structure can be thicker than an edge of the bottom layer. This feature can reduce possible seams in a filling material used during fabrication of the contact structure, thereby allowing a position of the first conductive layer's end to be easier to control. Fourth, the manufacture of the contact structure described in the present disclosure is compatible with an isolation structure that is formed to separate a gate line structure into multiple segments. The isolation structure can help release stress in the gate line structure and can allow the conductive layer filling process to be performed in separate steps, thereby improving the quality and reliability of the conductive layers.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

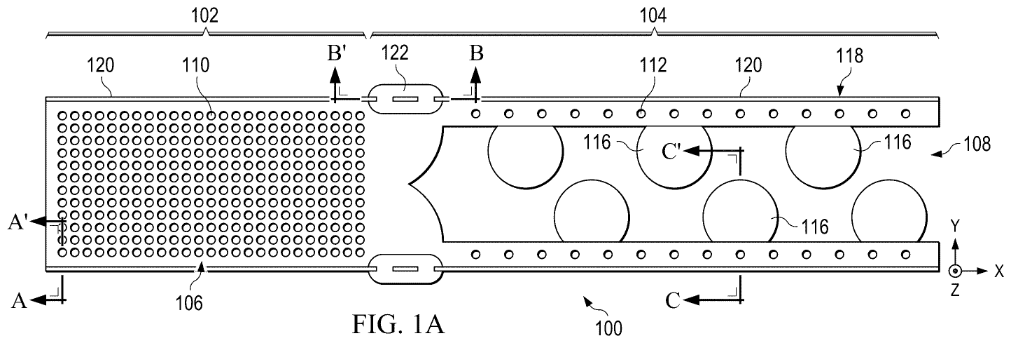

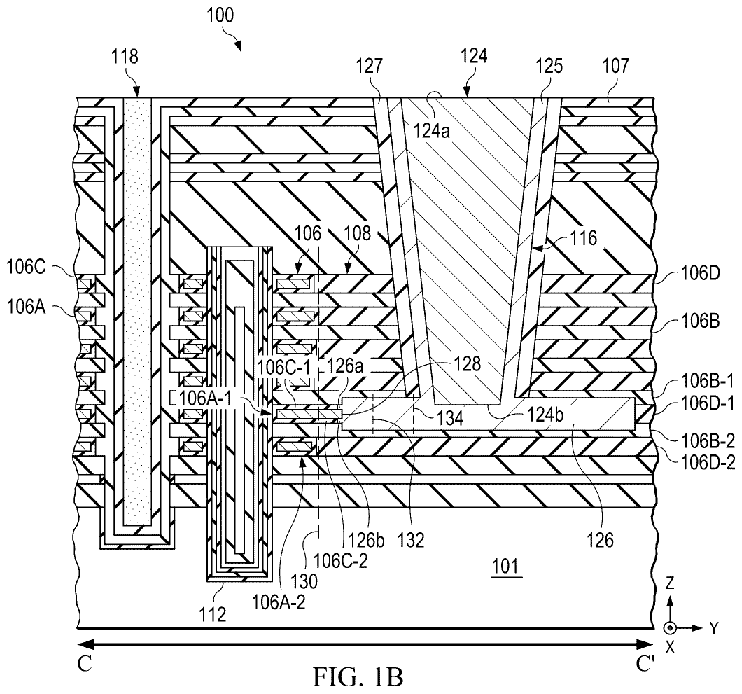

It is noted that X, Y, and Z axes (also referred to as X, Y, and Z directions) are included in FIGS. 1A-1B to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a stack 106 of alternating conductive layers and isolating layers (e.g., conductive layers 106A and isolating layers 106B as shown in FIG. 1B). In some implementations, a part of the stack 106 can be in the array region 102, and another part of the stack 106 can be in the connection region 104. The semiconductor device 100 further includes a stack 108 of alternating dielectric layers and isolating layers (e.g., dielectric layers 106D and isolating layers 108B as shown in FIG. 1B). In some implementations, the stack 108 can be in the connection region 104. The stack 106 is connected to the stack 108.

The semiconductor device 100 can include an array of channel structures 110 extending through the stack 106 in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the stack 106 in the connection region 104. In some implementations, the dummy channel structures 112 can be in one or more dummy regions or peripheral regions (not shown in FIG. 1A).

The semiconductor device 100 can include contact structures 116 in the connection region 104. A contact structure 116 can be configured to connect a corresponding one of the conductive layers of the stack 106 to a control circuit. The semiconductor device 100 can include one or more gate line structures 118. Each gate line structure 118 can extend in the X direction. The gate line structure 118 can extend into both the array region 102 and the connection region 104. In some implementations, the gate line structures 118 can divide an array region into multiple memory blocks. In some implementations, the gate line structure 118 can function as a common source contact for the channel structures 110 in the array region 102. As shown in FIG. 1A, each gate line structure 118 can include multiple segments 120 extending along the X direction. The segments 120 can be separated and spaced by isolation structures 122 along the X direction. The isolation structures 122 can eliminate or reduce stress built in the gate line structure 118 during the manufacturing process, thereby preventing the gate line structure 118 from bending or cracking. In some implementations (not shown in FIG. 1A), the gate line structure 118 can further include one or more segments extending along a second horizontal direction (e.g., the Y direction). In some implementations, the gate line structure 118 can include multiple segments connected in an H shape or a T shape. In some implementations, the segments 120 of each gate line structure 118 can have similar or a same width (e.g., along the Y direction). In some other implementations, the segments 120 of each gate line structure 118 can have different widths (e.g., along the Y direction). In some implementations, along the Y direction, a width of the segment 120 in the connection region 104 is larger than a width of the segment 120 in the array region 102. For example, the width of the segment 120 in the connection region 104 can be approximately 1.5 to 2 times that of the segment 120 in the array region 102.

FIG. 1B illustrates a cross-sectional view of the semiconductor device 100 along cut line CC′ of FIG. 1A. The semiconductor device 100 includes a substrate 101, the stack 106 of alternating conductive layers 106A and isolating layers 106B, and the stack 108 of alternating dielectric layers 106D and isolating layers 106B. Each isolating layer 106B can have a portion between two adjacent conductive layers 106A in the stack 106 and another portion between two adjacent dielectric layers 106D in the stack 108. The stack 106 and the stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100. The semiconductor device 100 can include a top layer 107 made of an isolating material (e.g., oxide).

The stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in the vertical direction (e.g., Z direction) perpendicular to the second horizontal direction. The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations, as illustrated in FIG. 1B, the stack 106 includes liner layers 106C. A liner layer 106C can cover part or all sides of a corresponding conductive layer 106A and be between the conductive layer 106A and two isolating layers 106B adjacent to the corresponding conductive layer 106A. The liner layer 106C can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material.

The stack 108 include dielectric layers 106D and isolating layers 106B alternating with each other along the vertical direction (e.g., Z direction). The stack 108 can be connected to the stack 106. The isolating layers 106B can extend into both the stack 106 and the stack 108 along the second horizontal direction (e.g., Y direction) in the connection region 104. A dielectric layer 106D in the stack 108 can extend to and be in contact with a corresponding conductive layer 106A (or a liner layer 106C surrounding the corresponding conductive layer 106A) in the stack 106. To fabricate the stack 106 and the stack 108, a series of alternating dielectric layers 106D and isolating layers 106B can be first formed. Then, dielectric layers 106D in a region of the stack 106 can be etched away, e.g., through an opening formed in the position of the gate line structure 118, while dielectric layers 106D in the stack 108 remain unchanged. Then, the liner layers 106C and the conductive layers 106A can be formed in replace of the dielectric layers 106D in the region of the stack 106 to form the stack 106.

The gate line structure 118 can extend through the stack 106 along the vertical direction (e.g., the Z direction). In some implementations, as shown in FIG. 1B, the gate line structure 118 can extend from the top layer 107 into the substrate 101 along the Z direction. The dummy channel structure 112 also can extend through the stack 106 along the vertical direction (e.g., the Z direction). In some implementations, as shown in FIG. 1B, the dummy channel structure 112 can extend into the substrate 101 along the Z direction. The contact structure 116 can extend through at least a part of the stack 108 (e.g., a set of dielectric layers 106D and isolating layers 106B of the stack 108) along the Z direction. As shown in FIG. 1B, the contact structure 116 can include a body 124, an outer layer 125, and a bottom layer 126. The body 124 and the outer layer 125 can extend along the Z direction, and the bottom layer 126 can extend in the X-Y plane (e.g., perpendicular to the Z direction). The outer layer 125 can be surrounding and in contact with the body 124. The body 124 and the outer layer 125 can be connected to the bottom layer 126. The body 124 can include a first conductive material. Both the outer layer 125 and the bottom layer 126 can include a same conductive material, which can be referred to as a second conductive material and can be different from the first conductive material of the body 124. In some implementations, the first conductive material can be a metallic material such as W, and the second conductive material can be TiN. In some implementations, the contact structure 116 can be surrounded by a contact spacer 127, and the contact spacer 127 can include a dielectric material (e.g., silicon oxide).

The body 124 has an end 124a and an end 124b opposite to one another along the Z direction. The end 124a is closer to the top layer 107 than the end 124b along the Z direction. The end 124a can be exposed from the top layer 107 and can be configured to be coupled out to an external circuit (e.g., a control circuit). The end 124b is connected to the bottom layer 126. The bottom layer 126 of each contact structure 116 can be coupled to a respective conductive layer 106A of the stack 106. For example, as shown in FIG. 1B, the bottom layer 126 is coupled to a conductive layer 106A-1. Both of the bottom layer 126 and the conductive layer 106A-1 are between two adjacent isolating layers 106B-1 and 106B-2 along the Z direction. The bottom layer 126 is in contact with an end 128 (also referred to as an end portion) of the conductive layer 106A-1 along the Y direction. The stack 106 can include another conductive layer 106A-2 that is not connected to the bottom layer 126. The conductive layer 106A-2 has an end 130 (or an end portion) in contact with a dielectric layer 106D-2 of the stack 108. The end 128 of the conductive layer 106A-1 is between the end 130 of the conductive layer 106A-2 and the body 124 of the contact structure 116 along the Y direction. In other words, the end 128 of the conductive layer 106A-1 is farther away from the gate line structure 118 than the end 130 of the conductive layer 106A-2 along the Y direction. The end portion 128 can have a surface that is in contact with the bottom layer 126 and extends along the X direction. It is understood that in practice, the surface of the end portion 128 may not be flat and may include a curved portion. The end portion 130 can have a surface that is in contact with the dielectric layer 106D-2 and extends along the X direction. Similarly, the surface of the end portion 130 may not be flat and may include a curved portion.

The conductive layer 106A-1 can be in contact with liner layers 106C-1 and 106C-2 of the stack 106 at a position of the end 130 of the conductive layer 106A-2 along the Y direction. The liner layer 106C-1 is between the conductive layer 106A-1 and the isolating layer 106B-1 along the Z direction. The liner layer 106C-2 is between the conductive layer 106A-1 and the isolating layer 106B-2 along the Z direction. The bottom layer 126 can include two portions 126a and 126b both in contact with the end 128 of the conductive layer 106A-1. For example, the portion 126a can be between the conductive layer 106A-1 and the isolating layer 106B-1 along the Z direction. The portion 126a can be in contact with the liner layer 106C-1 along the Y direction. The portion 126b can be between the conductive layer 106A-1 and the isolating layer 106B-2 along the Z direction. The portion 126b can be in contact with the liner layer 106C-2 along the Y direction.

In some implementations, along the Z direction, a center (closer to the body 124 along the Y direction) of the bottom layer 126 can be thicker than an edge (farther away from the body 124 along the Y direction) of the bottom layer 126. For example, the bottom layer 126 can have two cross sections 132 and 134 perpendicular to the Y direction. The cross sections 132 and 134 can be between the end 128 of the conductive layer 106A-1 and the body 124 (e.g., along the Y direction). The cross section 132 is closer to the end 128 of the conductive layer 106A-1 than the cross section 134 along the Y direction. A size of the cross section 132 along the Z direction is smaller than a size of the cross section 134 along the Z direction.

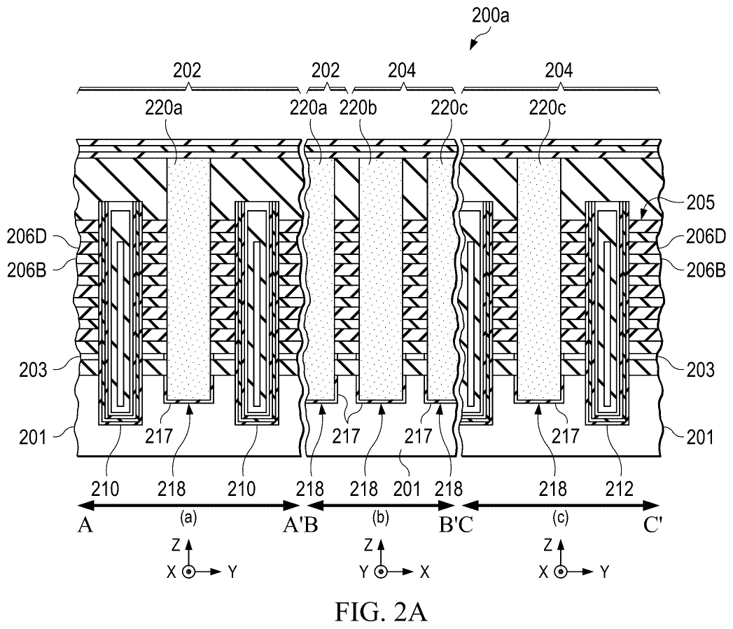

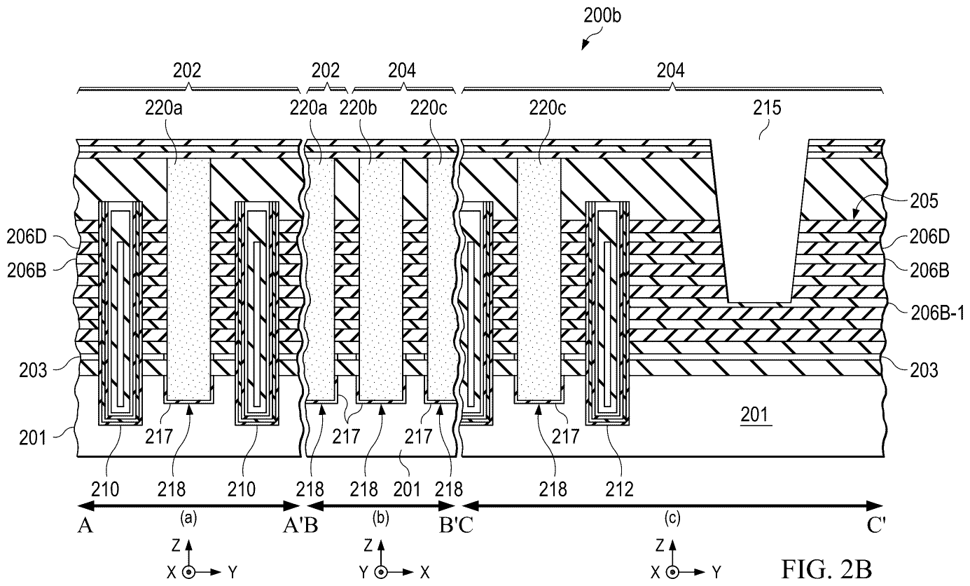

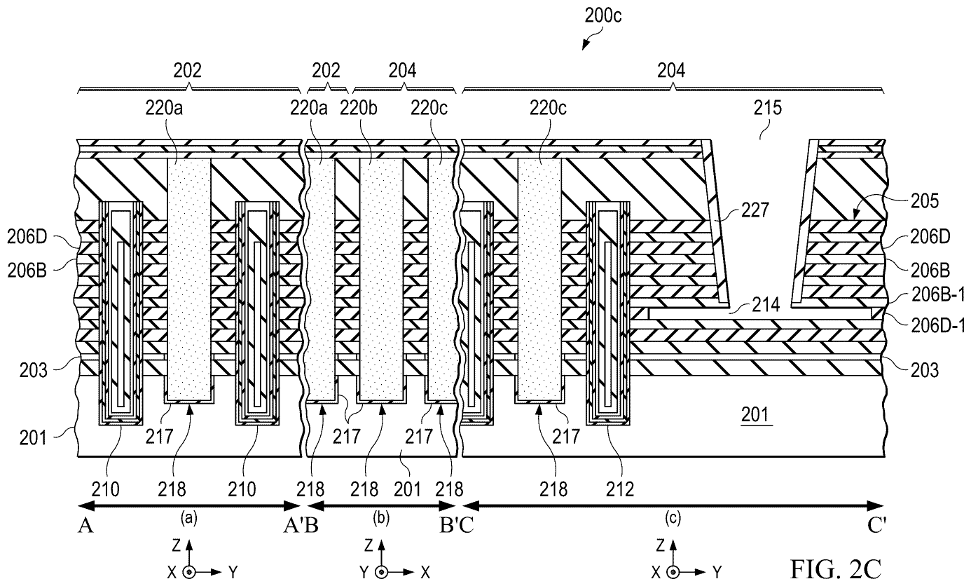

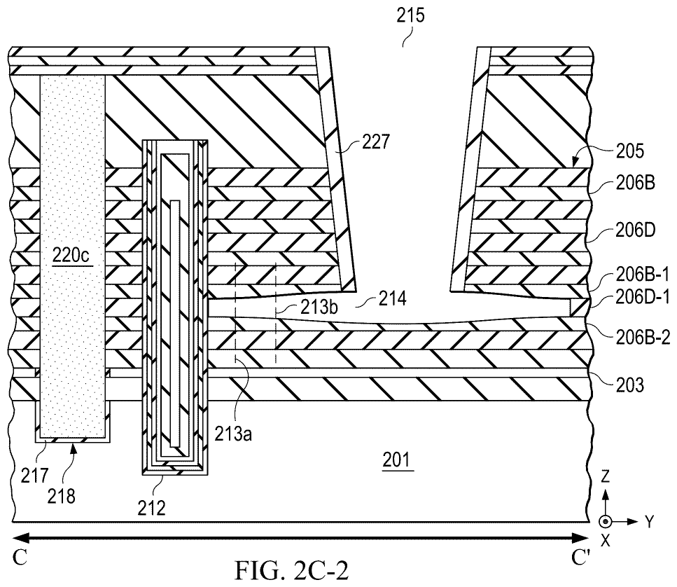

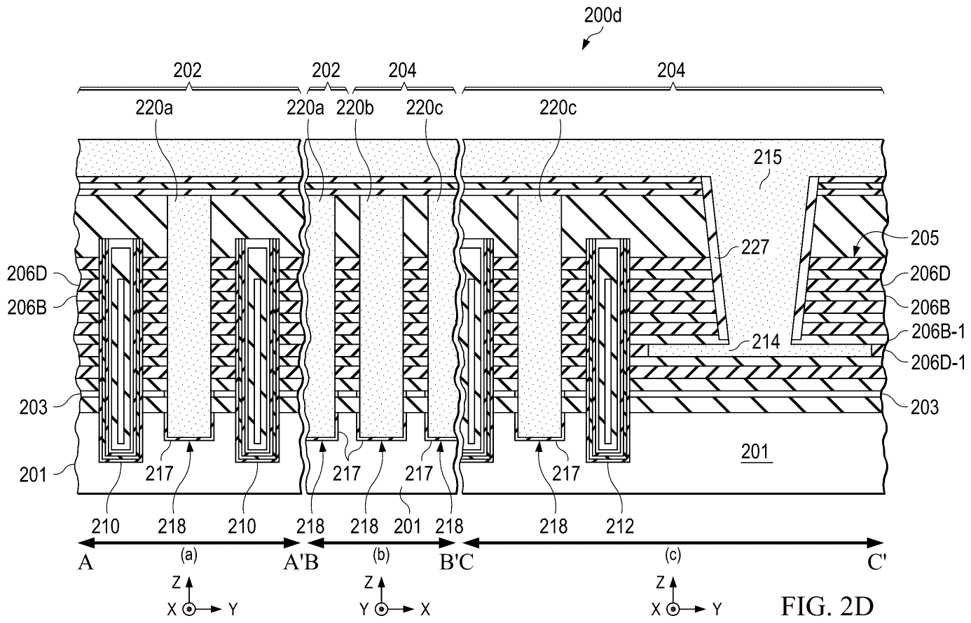

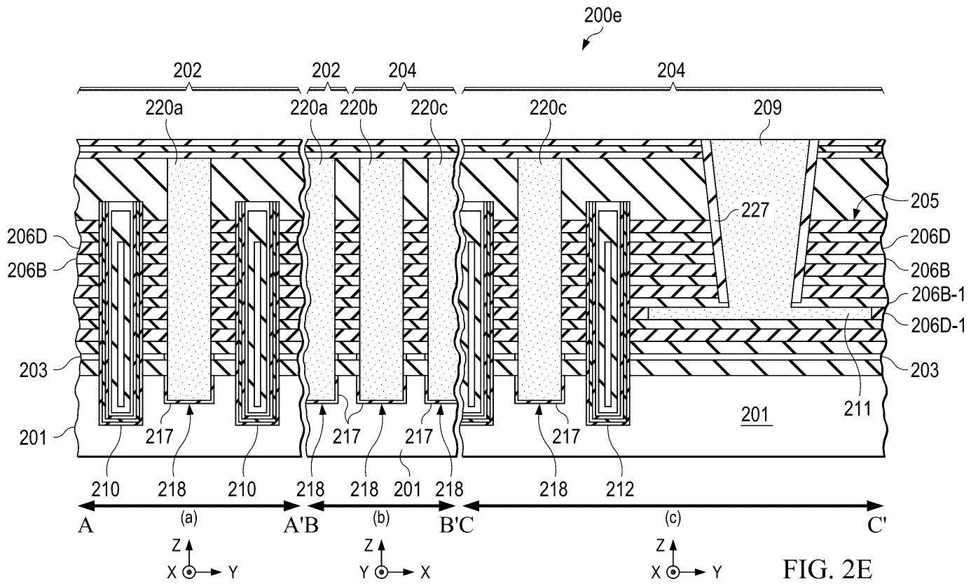

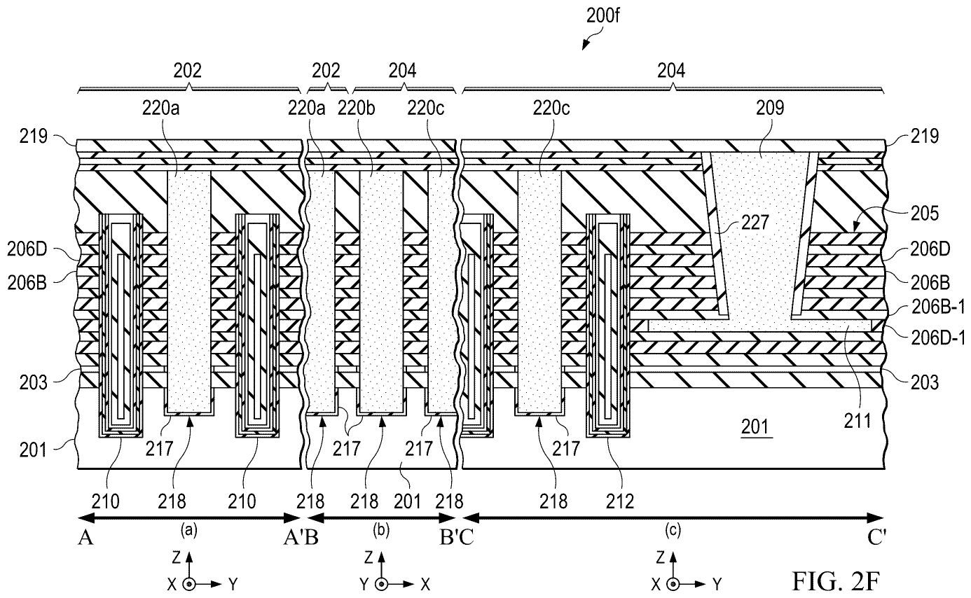

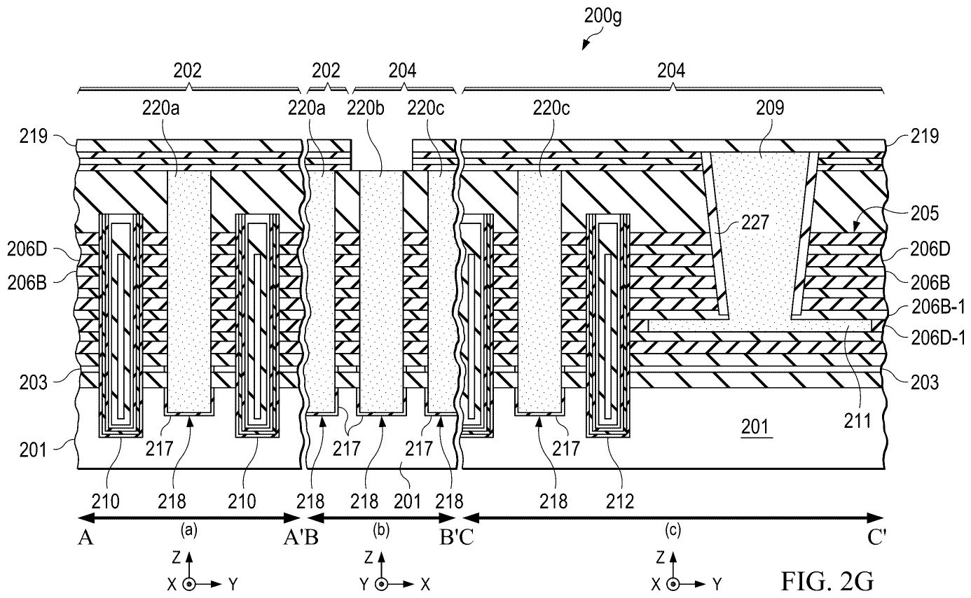

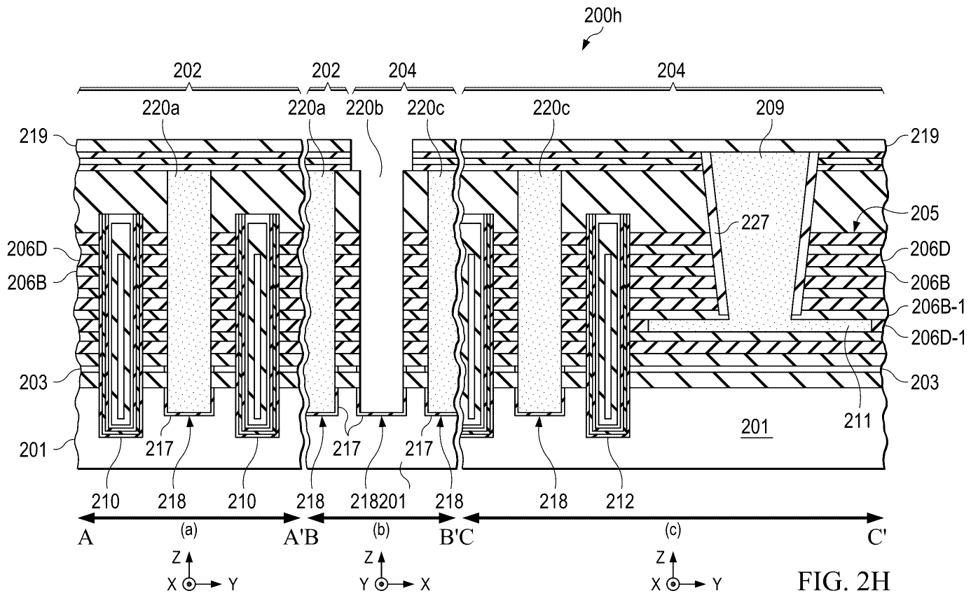

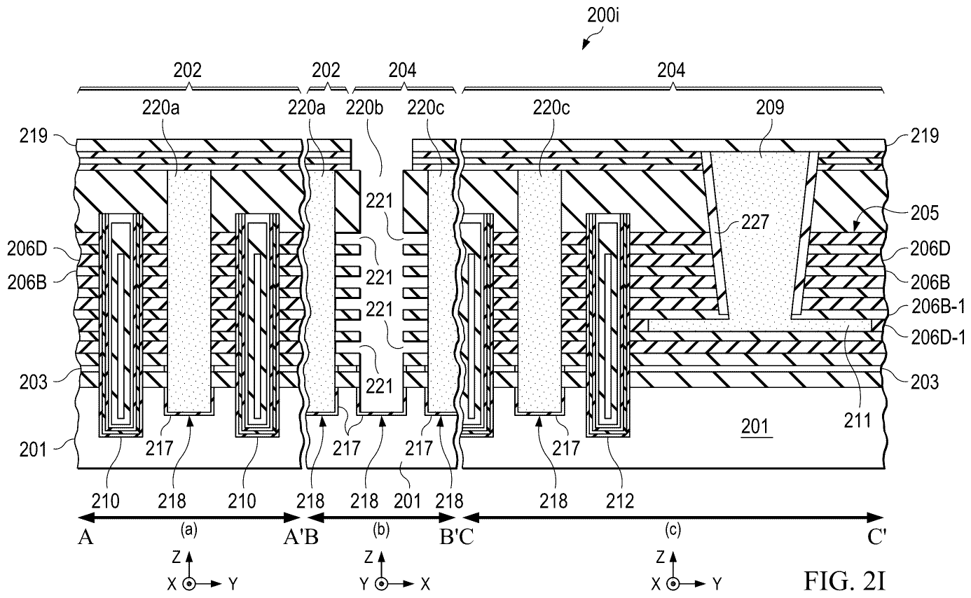

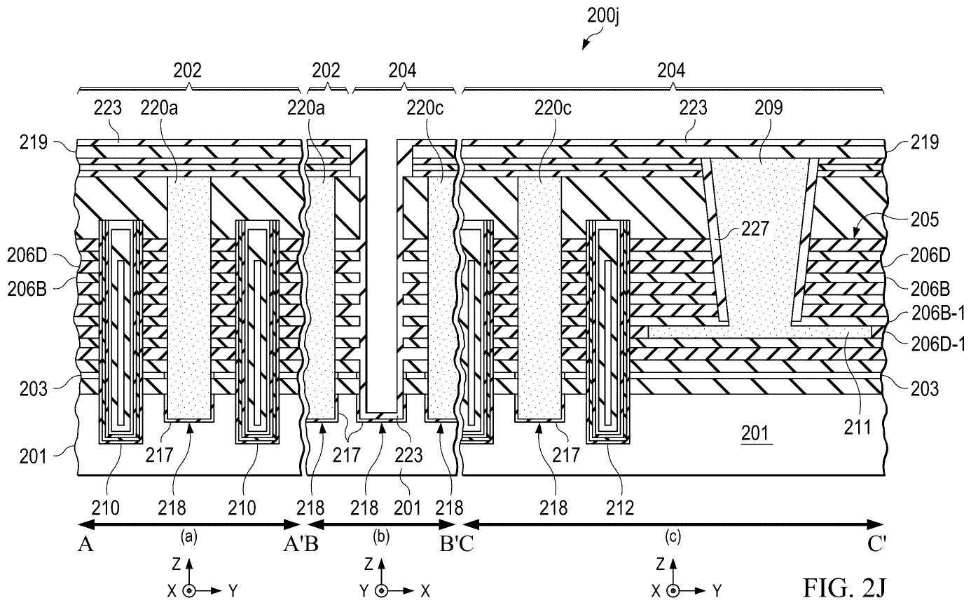

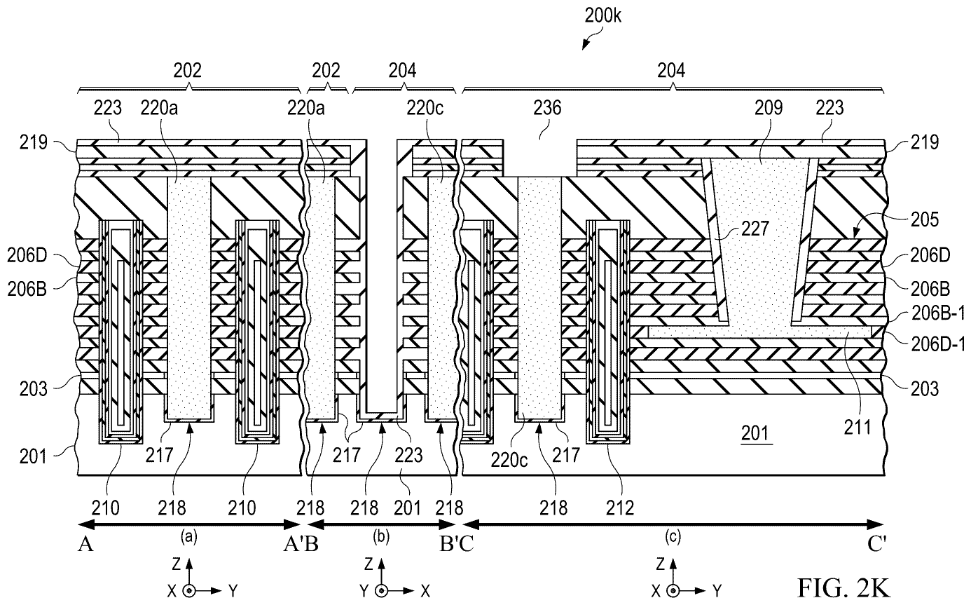

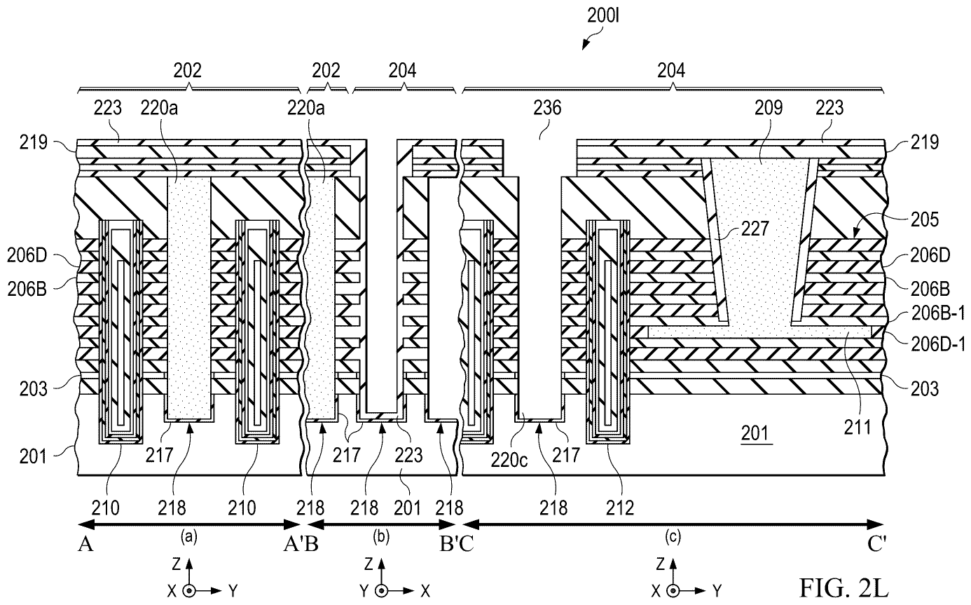

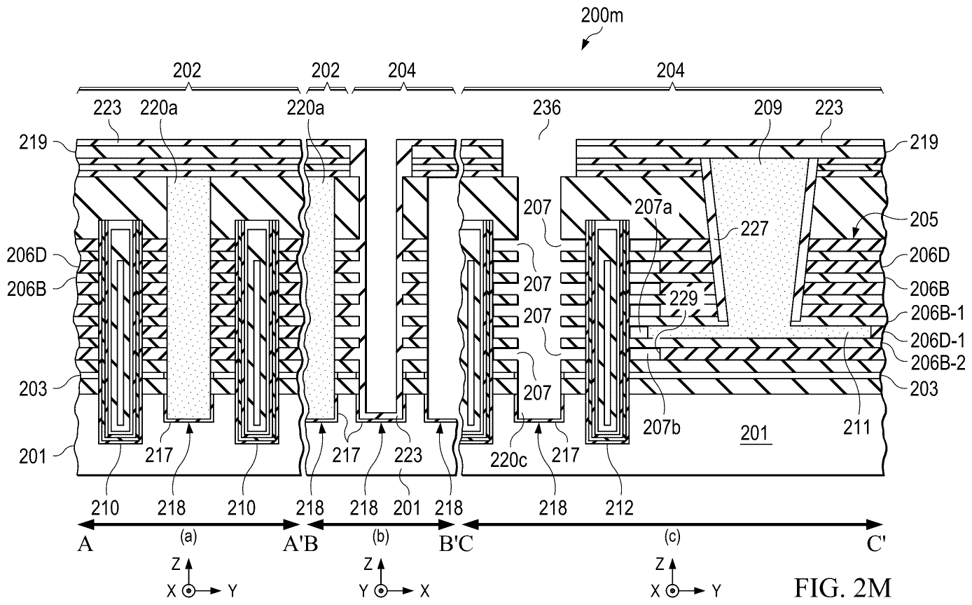

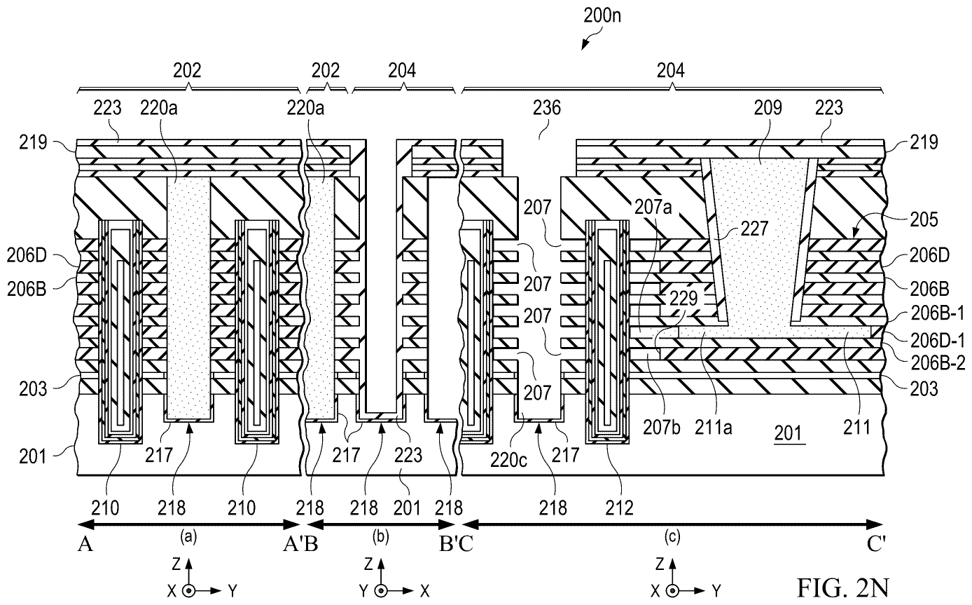

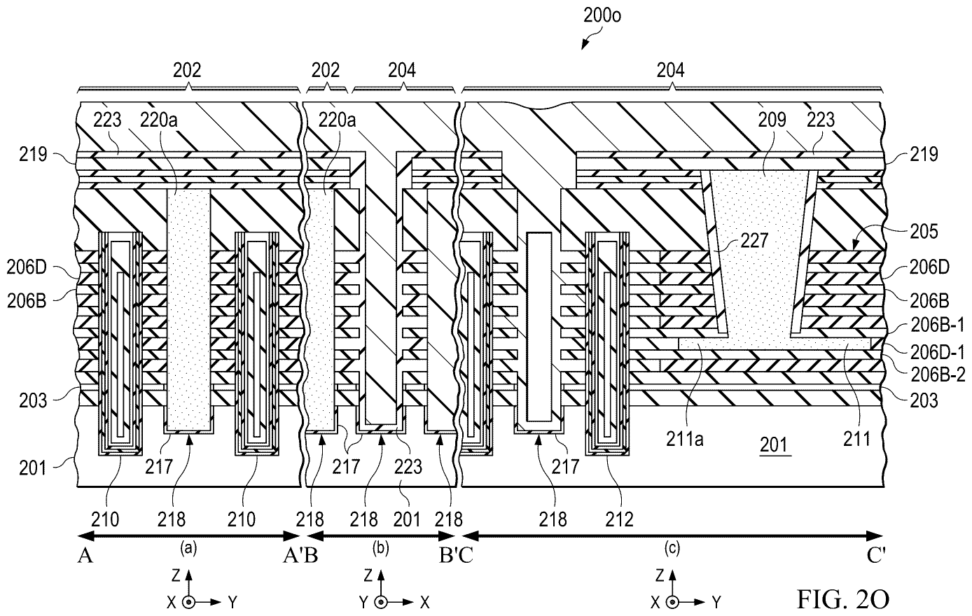

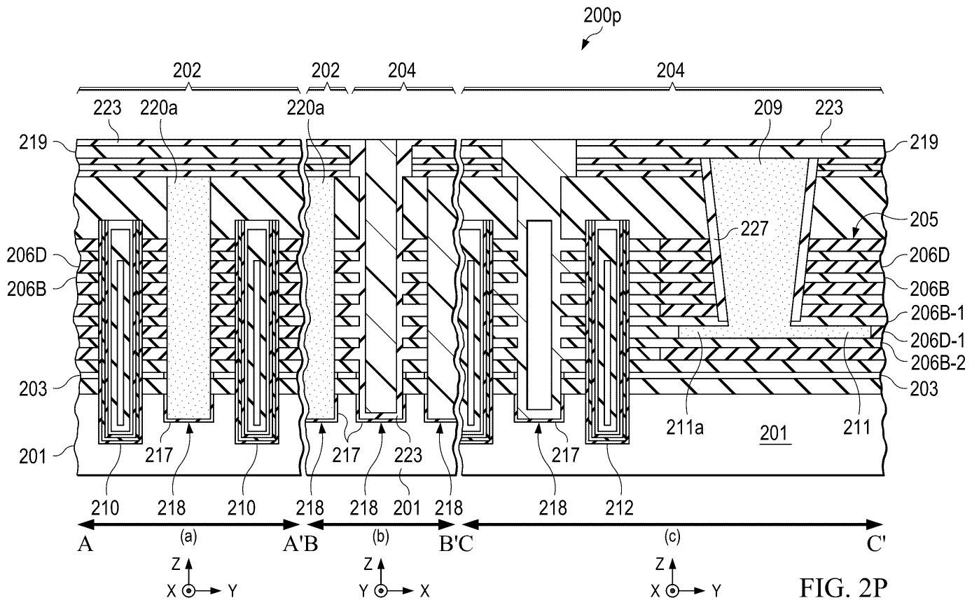

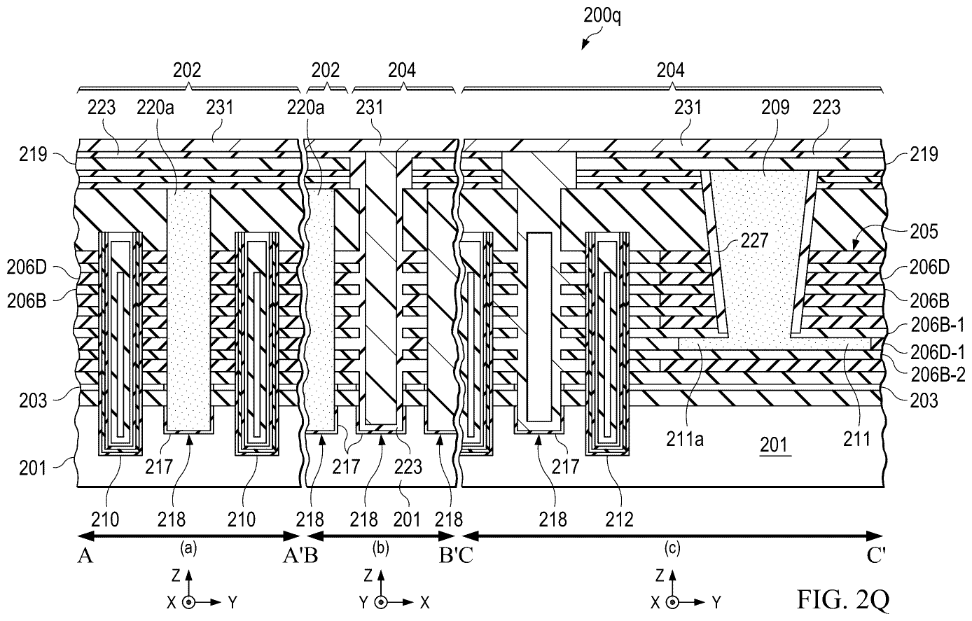

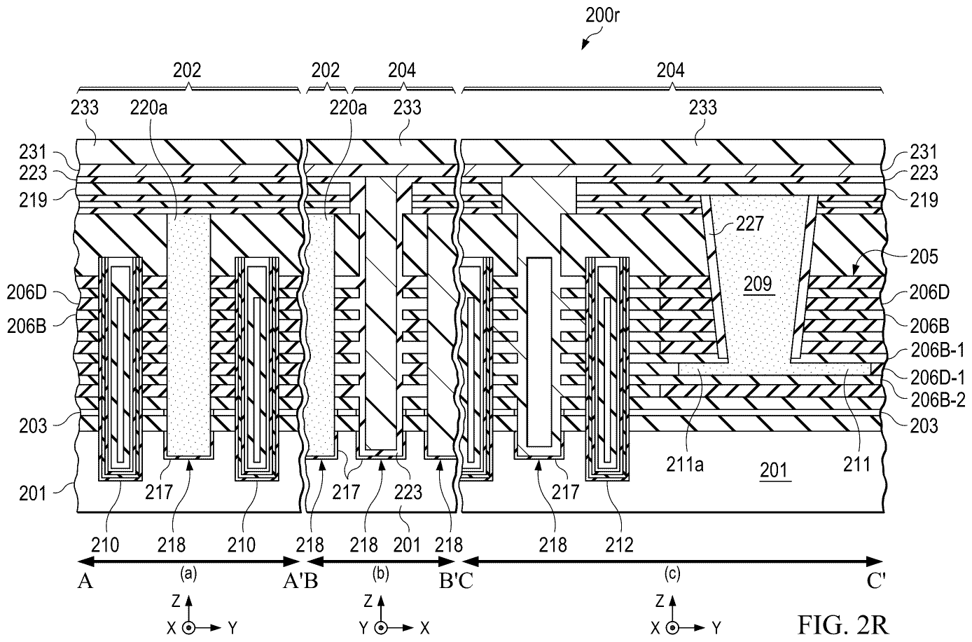

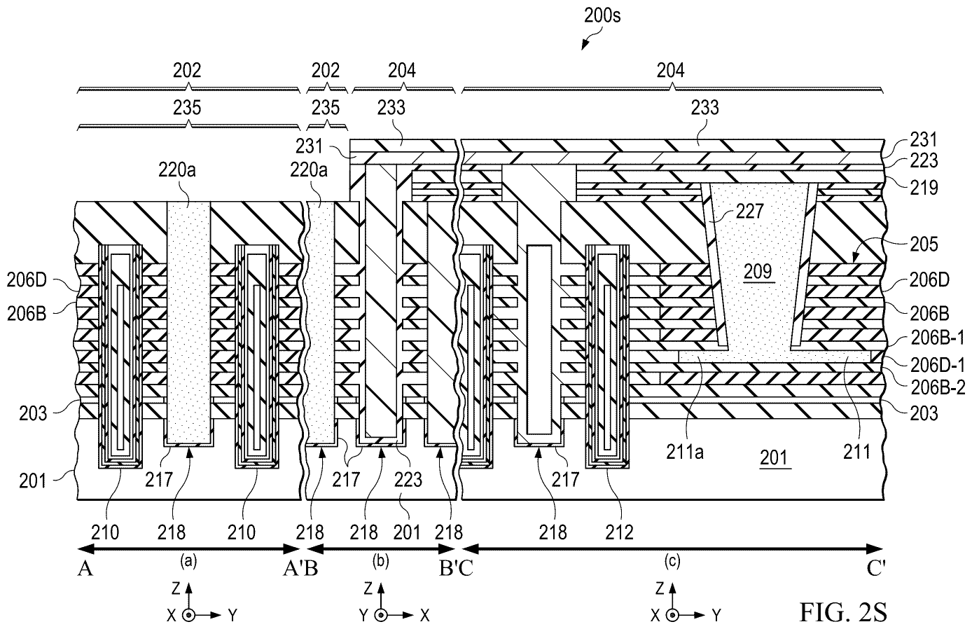

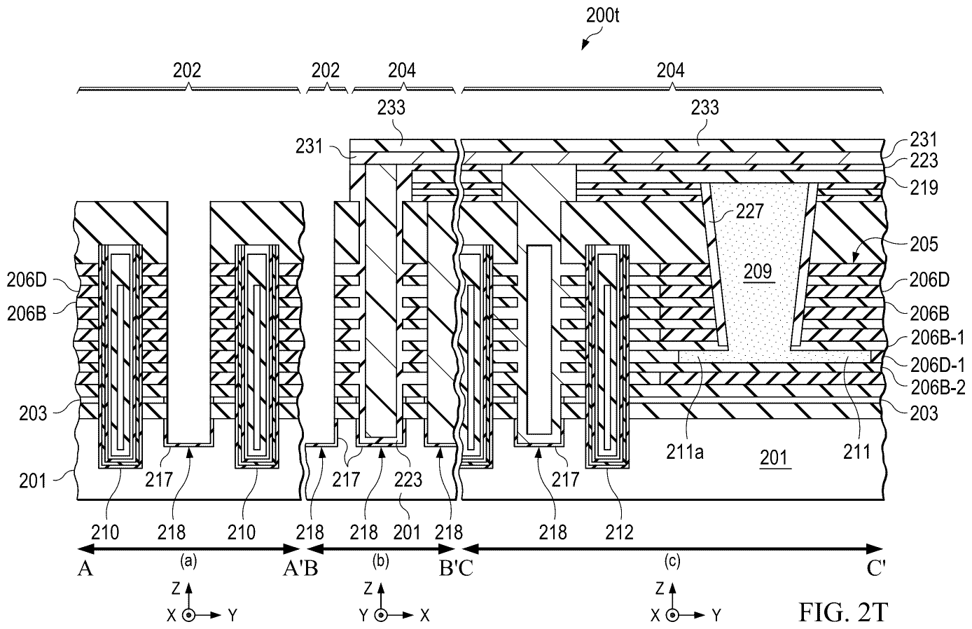

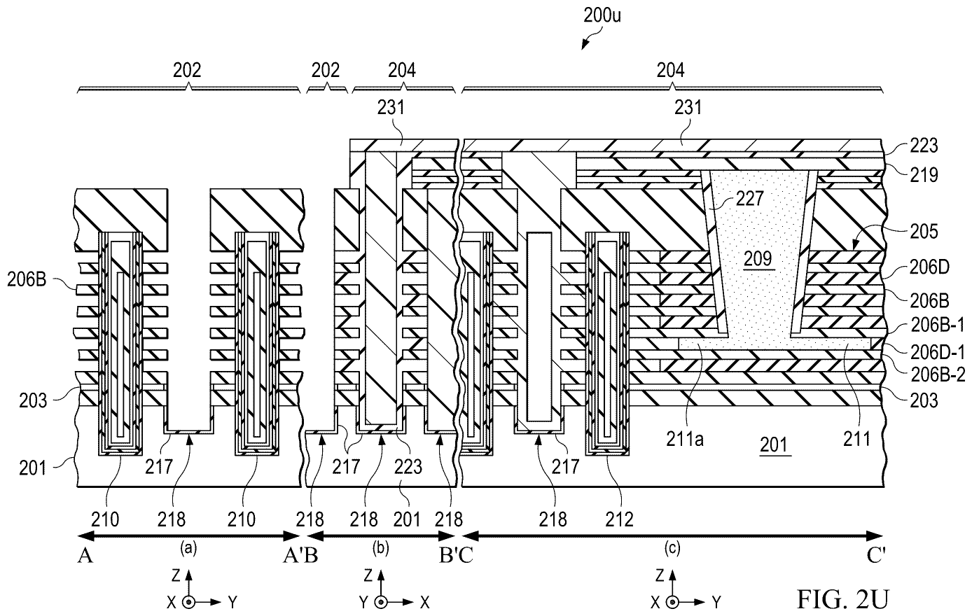

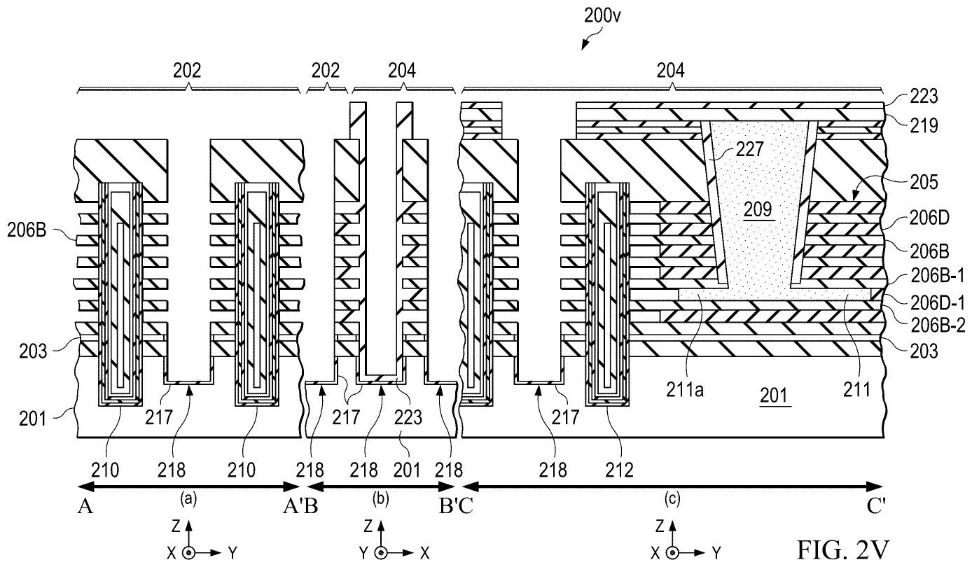

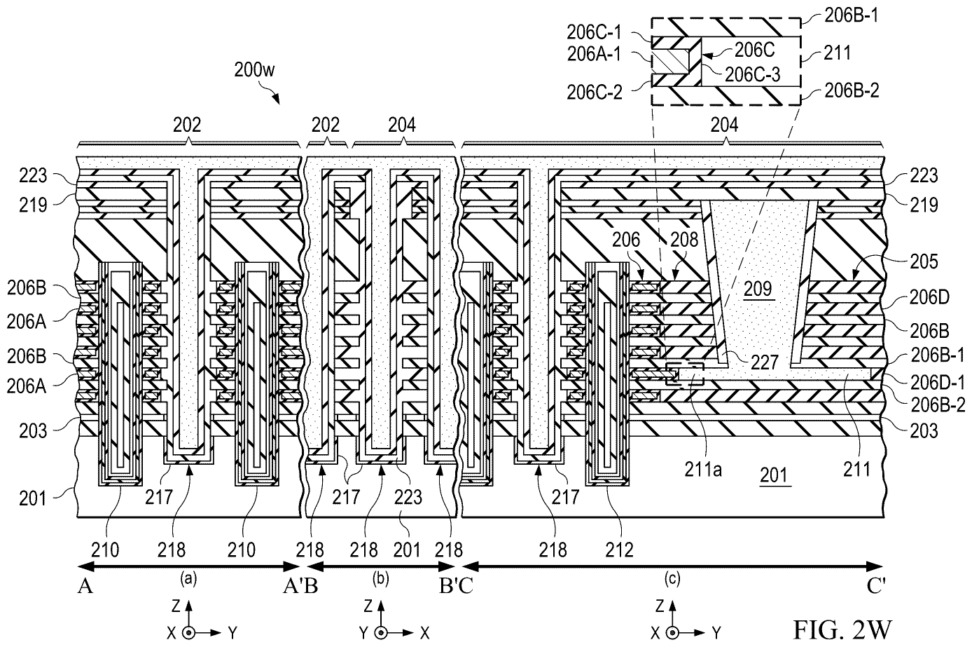

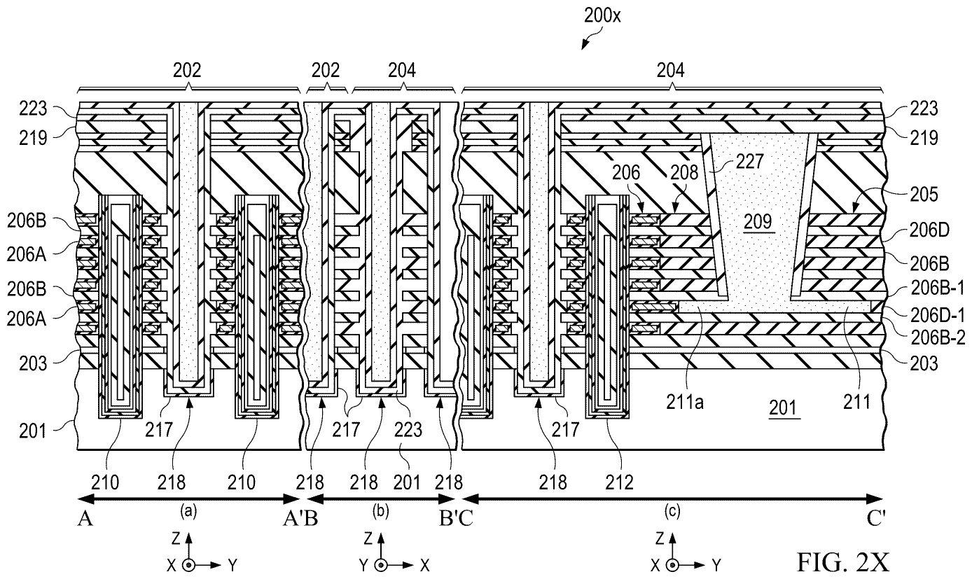

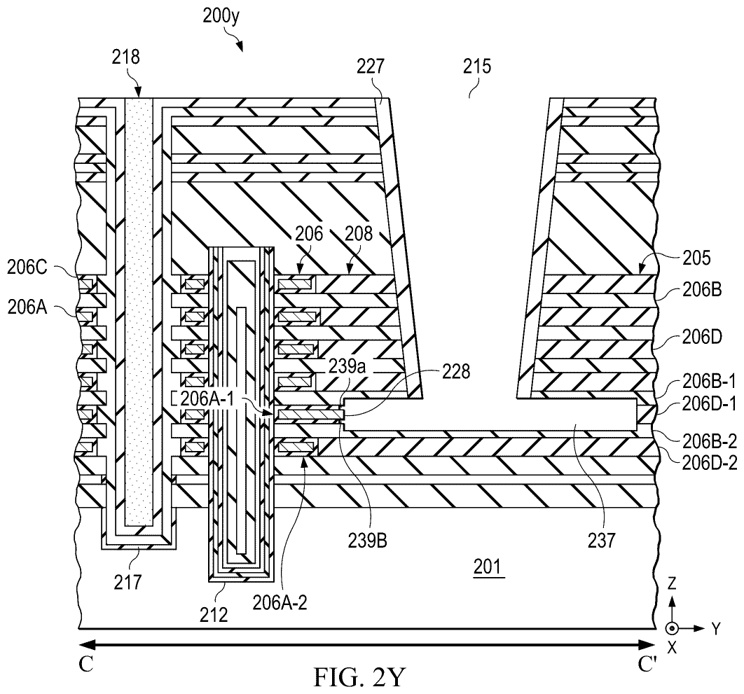

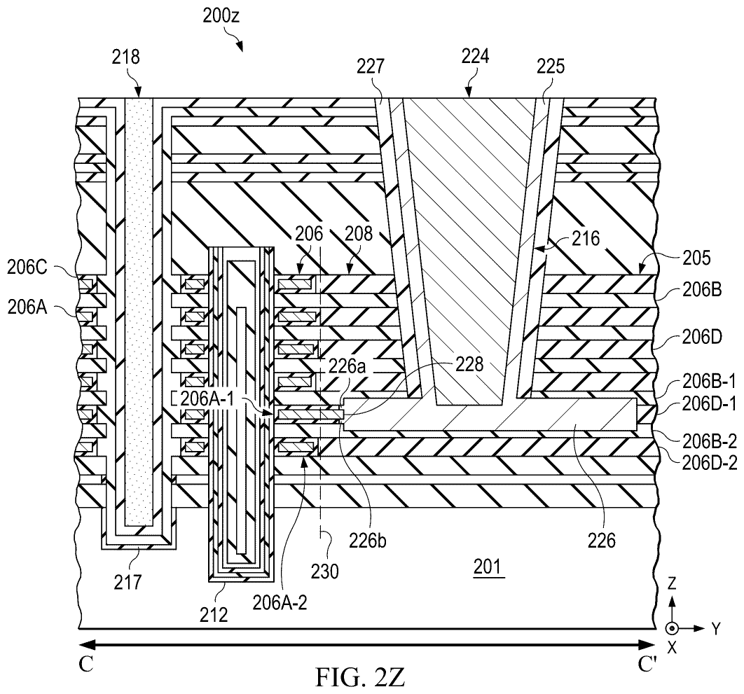

FIGS. 2A-2Z illustrate an example process of fabricating a semiconductor device, such as the semiconductor device 100 as illustrated in FIGS. 1A-1B. FIGS. 2A-2Z show cross-sectional views of example semiconductor structures at various stages of the fabrication process. Specifically, FIGS. 2A(a)-2X(a) illustrate cross-sectional views of example semiconductor structures along the cut line AA′ of FIG. 1A, FIGS. 2A(b)-2X(b) illustrate cross-sectional views of the example semiconductor structures along the cut line BB′ of FIG. 1A, and FIGS. 2A(c)-2C(c), 2C-2, 2D(c)-2X(c), 2Y, and 2Z illustrate cross-sectional views of the example semiconductor structures along the cut line CC′ of FIG. 1A.

As shown in FIG. 2A, a semiconductor structure 200a is formed. The semiconductor structure 200a can have an array region 202 and a connection region 204 adjacent to the array region 202 (e.g., along the X direction). The array region 202 can be an example of the array region 102 of the semiconductor device 100 of FIG. 1A, and the connection region 204 can be an example of the connection region 104 of the semiconductor device 100. The semiconductor structure 200a includes a substrate 201 and a stack 205 of alternating sacrificial layers 206D (also referred to as dielectric layers) and isolating layers 206B provided over the substrate 201. The stack 205 can extend across the array region 202 and the connection region 204. The sacrificial layers 206D and the isolating layers 206B can alternate in the vertical direction (e.g., the Z direction). The isolating layers 206B can include dielectric material, such as silicon oxide, silicon nitride, silicon oxynitride, or any combination thereof. In some implementations, the sacrificial layers 206D can include a dielectric material different from the dielectric material of the isolating layers 206B. For example, the isolating layers 206B can include silicon oxide, and the sacrificial layers 206D can include silicon nitride. In some implementations, the semiconductor structure 200a can further include a polysilicon layer 203 between the stack 205 and the substrate 201 along the vertical direction.

The semiconductor structure 200a can include channel structures 210 (as shown in FIG. 2A(a)) in the array region 202 and dummy channel structures 212 (as shown in FIG. 2A(c)) in the connection region. Each channel structure 210 can be similar to, or same as, the channel structure 110 of the semiconductor device 100 as shown in FIG. 1A. Each dummy channel structure 212 can be similar to, or same as, the dummy channel structure 112 of the semiconductor device 100 as shown in FIG. 1A.

The semiconductor structure 200a can include a gate line slit 218 extending along the X direction. The gate line slit 218 can extend through the stack 205 along the Z direction. As shown in FIG. 2A(b), the gate line slit 218 can include segments 220a, 220b, and 220c separated by a part of the stack 205 along the X direction. The segment 220b is between the segments 220a and 220c along the X direction. Protection structures 217 (e.g., poly oxidation) can be formed on bottoms (which can be in contact with the substrate 201) of the segments 220a-220c of the gate line slit 218 to protect the substrate 201. A filling material (e.g., poly silicon) can be filled into the gate line slit 218.

FIG. 2B illustrates a semiconductor structure 200b. The semiconductor structure 200b can be formed by forming a contact hole 215 in the connection region 204 by an etching process. The contact hole 215 can extend from a top (e.g., a surface farther away from the substrate 201) of the semiconductor structure 200b to an isolating layer 206B-1 of the stack 205.

As shown in a semiconductor structure 200c of FIG. 2C, a contact spacer 227 can be deposited on an inner surface of the contact hole 215. The contact hole 215 can be deepened to reach a sacrificial layer 206D-1 of the stack 205. The sacrificial layer 206D-1 is below the isolating layer 206B-1 and is in contact with the isolating layer 206B-1. A space 214 can be formed in the sacrificial layer 206D-1 by removing a portion of the sacrificial layer 206D-1 (e.g., through an etching process). In some implementations, the contact spacer 227 can protect the sacrificial layers 206D exposed by the contact hole 215 from being affected by the etching process.

In some implementations, as shown in FIG. 2C-2, the etching process can cause the space 214 expanded at a position closer to the contact hole 215. For example, a first etchant can be used during a first time period of the etching process. The first etchant can etch off the sacrificial layer 206D-1 and two isolating layers 206B-1 and 206B-2 adjacent to the sacrificial layer 206D-1. Thus, a first portion of the sacrificial layer 206D-1 and portions of the isolating layers 206B-1 and 206B-2 can be etched off during the first time period of the etching process. A second etchant can be used during a second time period of the etching process. The second etchant can etch off the sacrificial layer 206D-1 and has less or no effect on the isolating layers 206B-1 and 206B-2. Thus, a second portion of the sacrificial layer 206D-1 can be etched off during the second time period of the etching process. As shown in FIG. 2C-2, a size of the space 214 along the Z direction at a position 213a is smaller than a size of the space 214 along the Z direction at a position 213b. The positions 213a and 213b are arranged along the Y direction between the gate line slit 218 and the contact hole 215. The position 213a is closer to the gate line slit 218 than the position 213b along the Y direction.

FIG. 2D illustrates a semiconductor structure 200d, which can be formed by filling a filling material (e.g., poly silicon) into the contact hole 215 and the space 214.

FIG. 2E illustrates a semiconductor structure 200e, which can be formed by performing a planarization process, such as chemical mechanical polishing (CMP), to remove the excess filling material on top of the semiconductor structure 200d. The semiconductor structure 200e includes a filling body 209 in the contact hole 215 and a filling layer 211 in the space 214. The filling body 209 is connected to the filling layer 211 along the Z direction. The filling layer 211 extends along the Y direction.

FIG. 2F illustrates a semiconductor structure 200f, which can be formed by depositing a dielectric layer 219 (e.g., silicon oxide) on top of the semiconductor structure 200c.

As shown by semiconductor structure 200g in FIG. 2G, an opening is formed on top of the segment 220b of the gate line slit 218 to expose the filling material in the segment 220b. The opening can extend from a top surface of the dielectric layer 219 to the filling material in the segment 220b along the Z direction.

As shown by semiconductor structure 200h in FIG. 2H, the filling material in the segment 220b can be removed.

FIG. 2I illustrates a semiconductor structure 200i. The semiconductor structure 200i includes recesses 221 connected to the segment 220b of the gate line slit 218. The recesses 221 can be formed by removing (e.g., through etching) a portion of each sacrificial layer 206D that is exposed by the segment 220b of the gate line slit 218.

FIG. 2J illustrates a semiconductor structure 200j including a dielectric layer 223. The dielectric layer 223 can be formed by depositing a dielectric material (e.g., silicon oxide) in the recesses 221 and on an inner surface of the segment 220b of the gate line slit 218. In some implementations, the dielectric layer 223 can be referred to as an isolation structure that separate the segment 220a of the gate line slit 218 from the segment 220c of the gate line slit 218. In some implementations, the isolation structure can also include a filling material (e.g., as described later with reference to FIG. 2W) surrounded by the dielectric layer 223 in the segment 220b of the gate line slit 218. In some implementations, the dielectric layer 223 can also cover a top of the dielectric layer 219.

FIG. 2K illustrates a semiconductor structure 200k including an opening 236 formed on top of the segment 220c of the gate line slit 218. The opening 236 can extend from a top of the semiconductor structure 200k to the filling material in the segment 220c along the Z direction.

As shown by semiconductor structure 2001 in FIG. 2L, the filling material in the segment 220c can be removed.

FIG. 2M illustrates a semiconductor structure 200m including tunnels 207 in the connection region 204. The tunnels 207 are connected to the segment 220c of the gate line slit 218 and are between the isolating layers 206B of the stack 205 in the connection region 204. In some implementations, the tunnels 207 can be formed by filling an etching solution to the segment 220c of the gate line slit 218 through the opening 236, thereby removing portions of the sacrificial layers 206D of the stack 205 in the connection region 204. The tunnels 207 can include a tunnel 207a and other tunnels (e.g., 207b). The tunnel 207a is aligned with the filling layer 211 and the sacrificial layer 206D-1 along the Y direction. The other tunnels are aligned with other corresponding sacrificial layers along the Y direction. For example, the tunnel 207b is aligned with a sacrificial layer 206D-2 along the Y direction. The tunnels 207a exposes the filling layer 211. The other tunnels expose ends of remaining portions of the corresponding sacrificial layers. For example, the tunnel 207b exposes an end 229 of a remaining portion of the sacrificial layer 206D-2. In some implementations, the end 229 is farther away from the segment 220c of the gate line slit 218 along the Y direction than an end of the filling layer 211 that is exposed by the tunnel 207a.

FIG. 2N illustrates a semiconductor structure 200n. The semiconductor structure 200n can be formed by removing a portion of the filling layer 211 and enlarging the tunnel 207a along the Y direction. The enlarged tunnel 207a exposes an end 211a of a remaining portion of the filling layer 211. The end 211a is farther away from the segment 220c of the gate line slit 218 along the Y direction than the ends of the remaining portions of the other sacrificial layers (e.g., the end 229 of the sacrificial layer 206D-2).

FIG. 2O illustrates a semiconductor structure 2000. The semiconductor structure 2000 can be formed by filling the segment 220c of the gate line slit 218 and the tunnels 207 with a filling material (e.g., carbon). In some implementations, the filling material can also be deposited in the segment 220b and on the top of semiconductor structure 2000 as shown in FIG. 2O.

FIG. 2P illustrates a semiconductor structure 200p, which is formed by removing excess filling material on its top surface using a planarization process (e.g., CMP).

FIG. 2Q illustrates a semiconductor structure 200q including a liner layer 231. The liner layer 231 can be formed by depositing a filling material (e.g., the same as the filling material in the segment 220c) on top of the semiconductor structure 200q.

FIG. 2R illustrates a semiconductor structure 200r including a dielectric layer 233 formed on top of the liner layer 231. The dielectric layer 233 can include any suitable dielectric material (e.g., silicon oxynitride).

FIG. 2S illustrates a semiconductor structure 200s including an opening 235 in the array region 202. An opening 235 can be formed on top of the segment 220a of the gate line slit 218 by etching off a portion of the top of the semiconductor structure 200r (which can include, for example, a portion of the liner layer 231 and a portion of the dielectric layer 233) to expose the filling material in the segment 220a.

FIG. 2T illustrates a semiconductor structure 200t. The semiconductor structure 200t is formed by removing the filling material in the segment 220a.

FIG. 2U illustrates a semiconductor structure 200u. The semiconductor structure 200u is formed by removing the sacrificial layers 206D of the stack 205 in the array region 202. The sacrificial layers 206D in the array region 202 can be removed, for example, by filling an etching solution through the segment 220a of the gate line slit 218. In some implementations, the dielectric layer 233 can also be removed by the above etching process.

FIG. 2V illustrates a semiconductor structure 200v. The semiconductor structure 200v is formed by removing the liner layer 231, the filling material in the segments 220b and 220c of the gate line slit 218, and the filling material in the tunnels 207.

FIG. 2W illustrates a semiconductor structure 200w including conductive layers 206A. The conductive layers 206A can be in the tunnels 207 in the connection region 204 and between isolating layers 206B in the array region 202. In some implementations, each conductive layer 206A can be surrounded by a respective liner layer 206C. The conductive layer 206A can include a conductive material (e.g., W). The liner layer 206C can include a high-K dielectric material (e.g., Al₂O₃). The liner layers 206C and the conductive layers 206A can be formed, for example, by depositing (e.g., through the segments 220a and 220c of the gate line slit 218) the high-K dielectric material and the conductive material into the tunnels 207 and the space between isolating layers 206B in the array region 202. A filling material (e.g., polysilicon) can be deposited into the segments 220a, 220b, and 220c of the gate line slit 218. In some implementations, the conductive layers 206A and portions of the isolating layers 206B between the conductive layers 206A form a stack 206. The sacrificial layers or dielectric layers 206D and portions of the isolating layers 206B between the sacrificial layers 206D form a stack 208. The stack 206 can be an example of the stack 106 of the semiconductor device 100 of FIG. 1B. The stack 208 can be an example of the stack 108 of the semiconductor device 100 of FIG. 1B.

A conductive layer 206A-1 can be aligned with the filling layer 211 along the Y direction. In some implementations, the conductive layer 206A-1 is surrounded by one of the liner layers 206C. As shown in FIG. 2W, the liner layer 206C can include segments 206C-1, 206C-2, and 206C-3. The segment 206C-1 is between the conductive layer 206A-1 and the isolating layer 206B-1 along the Z direction. The segment 206C-2 is between the conductive layer 206A-1 and the isolating layer 206B-2 along the Z direction. The segment 206C-3 is between the conductive layer 206A-1 and the filling layer 211 along the Y direction.

FIG. 2X illustrates a semiconductor structure 200x. The semiconductor structure 200x can be formed by removing the excess filling material on top of the semiconductor structure 200w (e.g., using a planarization process, such as CMP).

FIG. 2Y illustrates a semiconductor structure 200y. The semiconductor structure 200y can be formed by forming an opening on the top of the semiconductor structure 200x to expose the filling material in the contact hole 215, removing the filling material in the contact hole 215, and forming a space 237 aligned with the sacrificial layer 206D-1 (e.g., along the Y direction). The space 237 is formed by removing the filling material in the filling layer 211. The segment 206C-3 of the liner layer 206C can be etched off by an etching process to expose the conductive layer 206A-1. In some implementations, the etching process may remove a portion of the segment 206C-1 of the liner layer 206C (which portion was connected to the segment 206C-3) and a portion of the segment 206C-2 of the liner layer 206C (which portion was connected to the segment 206C-3) to form two recesses 239a and 239b. The recess 239a is between the conductive layer 206A-1 and the isolating layer 206B-1 along the Z direction. The recess 239b is between the conductive layer 206A-1 and the isolating layer 206B-2 along the Z direction. The space 237 can include the recesses 239a and 239b.

FIG. 2Z illustrates a semiconductor structure 200z including a contact structure 216. The semiconductor structure 200z can be similar to, or same as the semiconductor device 100 as shown in FIGS. 1A-1B. The contact structure 216 can include a body 224, an outer layer 225, and a bottom layer 226. The body 224 and the outer layer 225 can extend along the Z direction, and the bottom layer 226 can extend in the X-Y plane (e.g., perpendicular to the Z direction). The outer layer 225 is in contact with an inner surface of the contact hole 215. The bottom layer 226 is in the space 237 and is in contact with the conducive layer 206A-1. The bottom layer 226 can include a portion 226a in the recess 239a and a portion 226b in the recess 239b. The outer layer 225 of the contact structure 216 and the bottom layer 226 of the contact structure 216 can be formed, for example, by depositing a conductive material through the contact hole 215. The body 224 is surrounded by the outer layer 225. The body can be formed, for example, by depositing a conductive material into the contact hole 215. In some implementations, both the outer layer 225 and the bottom layer 226 can include the same conductive material. In some implementations, the conductive material of the outer layer 225 and the bottom layer 226 can be different from the conductive material of the body 224. For example, the conductive material of the outer layer 225 and the bottom layer 226 can be TiN, and the conductive material of the body 224 can be a metallic material such as W.

As shown in FIG. 2Z, the bottom layer 226 is in contact with an end 228 of the conductive layer 206A-1 along the Y direction. The stack 206 can include another conductive layer 206A-2 that is not connected to the bottom layer 226. The conductive layer 206A-2 has an end 230 in contact with a dielectric layer (also referred to as sacrificial layer) 206D-2 of the stack 208. The end 228 of the conductive layer 206A-1 is between the end 230 of the conductive layer 206A-2 and the body 224 of the contact structure 216 along the Y direction. In other words, the end 228 of the conductive layer 206A-1 is farther away from the gate line slit 218 than the end 230 of the conductive layer 206A-2 along the Y direction.

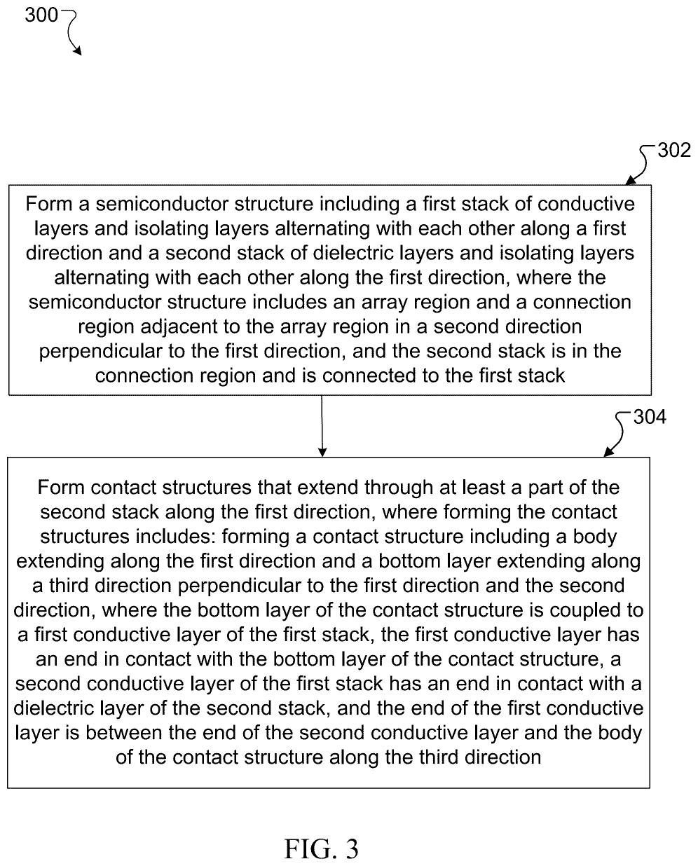

FIG. 3 illustrates a flow chart of an example process 300. The process 300 can be performed to form a semiconductor device (e.g., the semiconductor device 100 illustrated by FIGS. 1A-1B). The process 300 can be described in view of FIGS. 2A-2Z. The process 300 can include one or more steps of the fabrication process of forming the semiconductor structures in FIGS. 2A-2Z. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a semiconductor structure (e.g., the semiconductor structure 200w of FIG. 2W) is formed. The semiconductor structure includes a first stack (e.g., the stack 206) of conductive layers (e.g., the conductive layers 206A) and isolating layers (e.g., the isolating layers 206B) alternating with each other along a first direction (e.g., the Z direction) and a second stack (e.g., the stack 208) of dielectric layers (e.g., the dielectric layers 206D) and isolating layers (e.g., the isolating layers 206B) alternating with each other along the first direction. The semiconductor structure includes an array region (e.g., the array region 202) and a connection region (e.g., the connection region 204) adjacent to the array region in a second direction (e.g., the X direction) perpendicular to the first direction. The second stack is in the connection region and is connected to the first stack.

At operation 304, contact structures that extend through at least a part of the second stack along the first direction are formed. In some implementations, forming the contact structures includes forming a contact structure (e.g., the contact structure 216 of FIG. 2Z) that includes a body (e.g., the body 224) extending along the first direction and a bottom layer (e.g., the bottom layer 226) extending along a third direction (e.g., the Y direction) perpendicular to the first direction and the second direction. The bottom layer of the contact structure is coupled to a first conductive layer (e.g., the conductive layer 206A-1) of the first stack. The first conductive layer has an end (e.g., the end 228) in contact with the bottom layer of the contact structure. A second conductive layer (e.g., the conductive layer 206A-2) of the first stack has an end (e.g., the end 230) in contact with a dielectric layer (e.g., the dielectric layer 206D-2) of the second stack. The end of the first conductive layer is between the end of the second conductive layer and the body of the contact structure along the third direction.

In some implementations, the process 300 includes providing a stack (e.g., the stack 205 of FIG. 2A) of sacrificial layers (e.g., the sacrificial layers 206D) and isolating layers (e.g., the isolating layers 206B) alternating with each other along the first direction. The process 300 further includes forming a contact hole (e.g., the contact hole 215 of FIG. 2C) in the connection region. The contact hole extends into the stack along the first direction and reaches a first sacrificial layer (e.g., the sacrificial layer 206D-1 of FIG. 2C) of the sacrificial layers. The process 300 further includes forming a first space (e.g., the space 214 of FIG. 2C) in the first sacrificial layer by removing a portion of the first sacrificial layer. The process 300 further includes forming a filling body (e.g., the filling body 209 of FIG. 2E) in the contact hole and a filling layer (e.g., the filling layer 211 of FIG. 2E) in the first space by filling the contact hole and the first space with a first filling material. The filling body is connected to the filling layer, and the filling layer extends along the third direction (e.g., the Y direction) perpendicular to the first direction and the second direction.

In some implementations, forming the semiconductor structure includes forming a gate line slit (e.g., the gate line slit 218 of FIG. 2A) extending through the first stack along the first direction. The gate line slit includes a first segment (e.g., the segment 220a) in the array region and a second segment (e.g., the segment 220c) in the connection region. An isolation structure (e.g., the dielectric layer 223 of FIG. 2J) is between the first segment and the second segment (e.g., along the X direction).

In some implementations, forming the first space in the first sacrificial layer by removing the portion of the first sacrificial layer includes: etching off a first portion of the first sacrificial layer and portions of two isolating layers adjacent to the first sacrificial layer during a first time period of an etching process; and etching off a second portion of the first sacrificial layer during a second time period of the etching process (e.g., as described with reference to FIG. 2C-2). A size of the first space (e.g., the space 214 of FIG. 2C-2) along the first direction at a first position (e.g., the position 213a of FIG. 2C-2) is smaller than a size of the first space along the first direction at a second position (e.g., the position 213b of FIG. 2C-2). The first position and the second position are arranged along the third direction between the gate line slit and the contact hole. The first position is closer to the gate line slit than the second position along the third direction.

In some implementations, forming the semiconductor structure includes forming tunnels (e.g., the tunnels 207 of FIG. 2M) in the connection region by filling an etching solution through the second segment of the gate line slit to remove portions of the sacrificial layers in the connection region. The tunnels are between the isolating layers, and the second segment of the gate line slit extends through the tunnels along the first direction. The sacrificial layers include the first sacrificial layer (e.g., the sacrificial layer 206D-1 of FIG. 2M) and second sacrificial layers (e.g., the sacrificial layer 206D-2 of FIG. 2M). The tunnels include a first tunnel (e.g., the tunnel 207a of FIG. 2M) that is aligned with the filling layer and the first sacrificial layer along the third direction and second tunnels (e.g., the tunnel 207b of FIG. 2M) that are aligned with the second sacrificial layers along the third direction. The first tunnel exposes the filling layer, and the second tunnels expose ends (e.g., the end 229 of FIG. 2M) of remaining portions of the second sacrificial layers.

In some implementations, forming the semiconductor structure includes enlarging the first tunnel (e.g., the tunnel 207a of FIG. 2N) along the third direction (e.g., the Y direction) by removing a portion of the filling layer (e.g., the filling layer 211 of FIG. 2N). The enlarged first tunnel exposes an end (e.g., the end 211a) of a remaining portion of the filling layer. The end of the remaining portion of the filling layer is farther away from the second segment (e.g., the segment 220c) of the gate line slit (e.g., the gate line slit 218) along the third direction than the ends (e.g., the end 229 of FIG. 2N) of the remaining portions of the second sacrificial layers (e.g., the sacrificial layer 206D-2 of FIG. 2N).

In some implementations, forming the semiconductor structure further includes filling (e.g., as described with reference to FIG. 2O) the second segment (e.g., the segment 220c) of the gate line slit (e.g., the gate line slit 218) and the tunnels (e.g., the tunnels 207) with a second filling material (e.g., carbon). Forming the semiconductor structure further includes removing the sacrificial layers (e.g., the sacrificial layers 206D) in the array region by filling an etching solution through the first segment (e.g., the segment 220a) of the gate line slit. Forming the semiconductor structure further includes removing the second filling material in the second segment of the gate line slit and the tunnels (e.g., as described with reference to FIG. 2V). Forming the semiconductor structure further includes forming the first stack (e.g., the stack 206) by forming the conductive layers (e.g., the conductive layers 206A of FIG. 2W) of the first stack between the isolating layers (e.g., the isolating layers 206B of FIG. 2W). The conductive layers are formed by depositing at least a high-K dielectric material and a first conductive material (e.g., W) through the first segment of the gate line slit and the second segment of the gate line slit. The conductive layers include a first conductive layer (e.g., the conductive layer 206A-1 of FIG. 2W) surrounded by a liner layer (e.g., the liner layer 206C of FIG. 2W). The liner layer includes a first segment (e.g., the segment 206C-1 of FIG. 2W), a second segment (e.g., the segment 206C-2 of FIG. 2W), and a third segment (e.g., the segment 206C-3 of FIG. 2W) that are connected. The first conductive layer is between a first isolating layer (e.g., the isolating layer 206B-1 of FIG. 2W) and a second isolating layer (e.g., the isolating layer 206B-2 of FIG. 2W) that are adjacent to the first conductive layer. The first segment (e.g., 206C-1) of the liner layer is between the first conductive layer (e.g., 206A-1) and the first isolating layer (e.g., 206B-1) along the first direction (e.g., the Z direction). The second segment (e.g., 206C-2) of the liner layer is between the first conductive layer (e.g., 206A-1) and the second isolating layer (e.g., 206B-2) along the first direction (e.g., the Z direction). The third segment (e.g., 206C-3) of the liner layer is between the first conductive layer (e.g., 206A-1) and the filling layer (e.g., the filling layer 211 of FIG. 2W) along the third direction (e.g., the Y direction).

In some implementations, forming the semiconductor structure includes removing the first filling material in the contact hole (e.g., as described with reference to FIG. 2Y). Forming the semiconductor structure further includes forming a second space (e.g., the space 237 of FIG. 2Y) aligned with the first sacrificial layer (e.g., the sacrificial layer 206D-1 of FIG. 2Y) along the third direction (e.g., the Y direction) by removing the first filling material in the filling layer (e.g., the filling layer 211). Forming the semiconductor structure further includes removing the third segment of the liner layer (e.g., the segment 206C-3) to expose the first conductive layer. Forming the semiconductor structure further includes forming a first recess (e.g., the recess 239a of FIG. 2Y) between the first conductive layer and the first isolating layer by removing a portion of the first segment of the liner layer that was connected to the third segment of the liner layer. Forming the semiconductor structure further includes forming a second recess (e.g., the recess 239b of the FIG. 2Y) between the first conductive layer and the second isolating layer by removing a portion of the second segment of the liner layer that was connected to the third segment of liner layer.

In some implementations, forming the contact structure includes forming an outer layer (e.g., the outer layer 225 of FIG. 2Z) of the contact structure and the bottom layer (e.g., the bottom layer 226 of FIG. 2Z) of the contact structure by depositing a second conductive material (e.g., TiN) through the contact hole. The outer layer is in contact with an inner surface of the contact hole. The bottom layer of the contact structure is in the second space (e.g., the space 237 of FIG. 2Y) aligned with the first sacrificial layer and is in contact with the first conducive layer (e.g., the conductive layer 206A-1 of FIG. 2Z). The bottom layer of the contact structure includes a first portion (e.g., the portion 226a of FIG. 2Z) in the first recess and a second portion (e.g., the portion 226b) in the second recess. A body (e.g., the body 224 of FIG. 2Z) of the contact structure can be formed by depositing the first conductive material (e.g., W) into the contact hole. The body is surrounded by the outer layer.

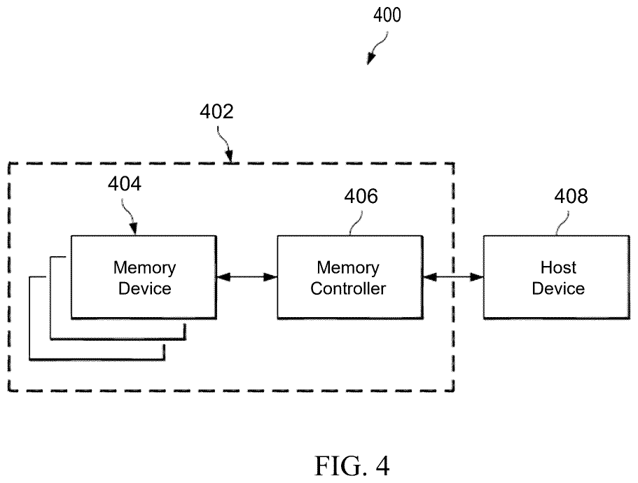

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed in the present disclosure, such as a memory device (e.g., a NAND Flash memory) as shown in FIGS. 1A-1B. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction and a second stack of dielectric layers and isolating layers alternating with each other along the first direction, wherein a connection region of the semiconductor device is adjacent to an array region of the semiconductor device in a second direction perpendicular to the first direction, and the second stack is in the connection region and is connected to the first stack; and
contact structures extending through at least a part of the second stack along the first direction, wherein a contact structure of the contact structures comprises a body extending along the first direction and a bottom layer extending along a third direction perpendicular to the first direction and the second direction,
wherein a first conductive layer of the first stack is coupled to the bottom layer of the contact structure, and the first conductive layer has an end in contact with the bottom layer of the contact structure, wherein a second conductive layer of the first stack has an end in contact with a dielectric layer of the second stack, and wherein the end of the first conductive layer is between the end of the second conductive layer and the body of the contact structure along the third direction.

2. The semiconductor device of claim 1, wherein the semiconductor device further comprises a gate line structure extending through the first stack along the first direction, the end of the first conductive layer is farther away from the gate line structure along the third direction than the end of the second conductive layer.

3. The semiconductor device of claim 2, wherein the first conductive layer is in contact with a first liner layer and a second liner layer at a position of the end of the second conductive layer along the third direction, the first liner layer is between the first conductive layer and a first isolating layer adjacent to the first conductive layer, and the second liner layer is between the first conductive layer and a second isolating layer adjacent to the first conductive layer.

4. The semiconductor device of claim 3, wherein the first liner layer comprises a high-K dielectric material, and the second liner layer comprises the high-K dielectric material.

5. The semiconductor device of claim 3, wherein the bottom layer of the contact structure comprises a first portion and a second portion,
wherein the first portion is between the first conductive layer and the first isolating layer along the first direction, the first portion is in contact with the first liner layer along the third direction, and
wherein the second portion is between the first conductive layer and the second isolating layer along the first direction, and the second portion is in contact with the second liner layer along the third direction.

6. The semiconductor device of claim 1, wherein the contact structure further comprises an outer layer surrounding the body, and the outer layer and the body are connected to the bottom layer of the contact structure, and
wherein the outer layer comprises a first conductive material, the bottom layer comprises the first conductive material, the body comprises a second conductive material, and the conductive layers comprise the second conductive material.

7. The semiconductor device of claim 1, wherein a size of the bottom layer of the contact structure along the first direction at a first position is smaller than a size of the bottom layer of the contact structure along the first direction at a second position, and
wherein the first position and the second position are along the third direction between the first conductive layer and the contact structure, and the first position is closer to the end of the first conductive layer than the second position along the third direction.

8. The semiconductor device of claim 1, wherein the contact structure is surrounded by a contact spacer that comprises a dielectric material.

9. A method of forming a semiconductor device, the method comprising:
forming a semiconductor structure comprising a first stack of conductive layers and isolating layers alternating with each other along a first direction and a second stack of dielectric layers and isolating layers alternating with each other along the first direction, wherein the semiconductor structure comprises an array region and a connection region adjacent to the array region in a second direction perpendicular to the first direction, and the second stack is in the connection region and is connected to the first stack; and
forming contact structures that extend through at least a part of the second stack along the first direction,
wherein forming the contact structures comprises:
forming a contact structure comprising a body extending along the first direction and a bottom layer extending along a third direction perpendicular to the first direction and the second direction, wherein the bottom layer of the contact structure is coupled to a first conductive layer of the first stack, and wherein the first conductive layer has an end in contact with the bottom layer of the contact structure,
wherein a second conductive layer of the first stack has an end in contact with a dielectric layer of the second stack, and wherein the end of the first conductive layer is between the end of the second conductive layer and the body of the contact structure along the third direction.

10. The method of claim 9, wherein the method comprises:
providing a stack of sacrificial layers and isolating layers alternating with each other along the first direction;
forming a contact hole in the connection region, wherein the contact hole extends into the stack along the first direction and reaches a first sacrificial layer of the sacrificial layers;
forming a first space in the first sacrificial layer by removing a portion of the first sacrificial layer; and
forming a filling body in the contact hole and a filling layer in the first space by filling the contact hole and the first space with a first filling material, wherein the filling body is connected to the filling layer, and the filling layer extends along the third direction.

11. The method of claim 10, wherein forming the semiconductor structure comprises:
forming a gate line slit extending through the first stack along the first direction,
wherein the gate line slit comprises a first segment in the array region and a second segment in the connection region, and an isolation structure is between the first segment and the second segment along the second direction.

12. The method of claim 11, wherein forming the first space in the first sacrificial layer by removing the portion of the first sacrificial layer comprises:
etching off a first portion of the first sacrificial layer and portions of two isolating layers adjacent to the first sacrificial layer during a first time period of an etching process; and
etching off a second portion of the first sacrificial layer during a second time period of the etching process,
wherein a size of the first space along the first direction at a first position is smaller than a size of the first space along the first direction at a second position, the first position and the second position are arranged along the third direction between the gate line slit and the contact hole, and the first position is closer to the gate line slit than the second position along the third direction.

13. The method of claim 11, wherein forming the semiconductor structure comprises:
forming tunnels in the connection region by filling an etching solution through the second segment of the gate line slit to remove portions of the sacrificial layers in the connection region, wherein the tunnels are between the isolating layers, and the second segment of the gate line slit extends through the tunnels along the first direction,
wherein the sacrificial layers comprise the first sacrificial layer and second sacrificial layers, the tunnels comprise a first tunnel that is aligned with the filling layer and the first sacrificial layer along the third direction and second tunnels that are aligned with the second sacrificial layers along the third direction, the first tunnel exposes the filling layer, and the second tunnels expose ends of remaining portions of the second sacrificial layers.

14. The method of claim 13, wherein forming the semiconductor structure comprises:
enlarging the first tunnel along the third direction by removing a portion of the filling layer, wherein the enlarged first tunnel exposes an end of a remaining portion of the filling layer, and the end of the remaining portion of the filling layer is farther away from the second segment of the gate line slit along the third direction than the ends of the remaining portions of the second sacrificial layers.

15. The method of claim 14, wherein forming the semiconductor structure comprises:
filling the second segment of the gate line slit and the tunnels with a second filling material;
removing the sacrificial layers in the array region by filling an etching solution through the first segment of the gate line slit;
removing the second filling material in the second segment of the gate line slit and the tunnels; and
forming the first stack by forming the conductive layers of the first stack between the isolating layers, wherein the conductive layers are formed by depositing at least a high-K dielectric material and a first conductive material through the first segment of the gate line slit and the second segment of the gate line slit, wherein the conductive layers comprise a first conductive layer surrounded by a liner layer, the liner layer comprises a first segment, a second segment, and a third segment that are connected, the first conductive layer is between a first isolating layer and a second isolating layer that are adjacent to the first conductive layer, the first segment of the liner layer is between the first conductive layer and the first isolating layer along the first direction, the second segment of the liner layer is between the first conductive layer and the second isolating layer along the first direction, the third segment of the liner layer is between the first conductive layer and the filling layer along the third direction.

16. The method of claim 15, wherein forming the semiconductor structure comprises:
removing the first filling material in the contact hole;
forming a second space aligned with the first sacrificial layer along the third direction by removing the first filling material in the filling layer;
removing the third segment of the liner layer to expose the first conductive layer;
forming a first recess between the first conductive layer and the first isolating layer by removing a portion of the first segment of the liner layer that was connected to the third segment of the liner layer; and
forming a second recess between the first conductive layer and the second isolating layer by removing a portion of the second segment of the liner layer that was connected to the third segment of the liner layer.

17. The method of claim 16, wherein forming the contact structure comprises:
forming an outer layer of the contact structure and the bottom layer of the contact structure by depositing a second conductive material through the contact hole, wherein the outer layer is in contact with an inner surface of the contact hole, and the bottom layer of the contact structure is in the second space aligned with the first sacrificial layer and is in contact with the first conducive layer, and the bottom layer of the contact structure comprises a first portion in the first recess and a second portion in the second recess; and
forming a body of the contact structure by depositing the first conductive material into the contact hole, wherein the body is surrounded by the outer layer.

18. A memory system, comprising:
a memory device; and
a memory controller coupled to the memory device and configured to control the memory device,
wherein the memory device comprises:
a first stack of conductive layers and isolating layers alternating with each other along a first direction and a second stack of dielectric layers and isolating layers alternating with each other along the first direction, wherein a connection region of the memory device is adjacent to an array region of the memory device in a second direction perpendicular to the first direction, and the second stack is in the connection region and is connected to the first stack; and
contact structures extending through at least a part of the second stack along the first direction, wherein a contact structure of the contact structures comprises a body extending along the first direction and a bottom layer extending along a third direction perpendicular to the first direction and the second direction,
wherein a first conductive layer of the first stack is coupled to the bottom layer of the contact structure, the first conductive layer has an end in contact with the bottom layer of the contact structure, a second conductive layer of the first stack has an end in contact with a dielectric layer of the second stack, and the end of the first conductive layer is between the end of the second conductive layer and the body of the contact structure along the third direction.

19. The memory system of claim 18, wherein the first conductive layer is in contact with a first liner layer and a second liner layer at a position of the end of the second conductive layer along the third direction, the first liner layer is between the first conductive layer and a first isolating layer adjacent to the first conductive layer, and the second liner layer is between the first conductive layer and a second isolating layer adjacent to the first conductive layer, and
wherein the bottom layer of the contact structure comprises a first portion and a second portion, the first portion is between the first conductive layer and the first isolating layer along the first direction, the first portion is in contact with the first liner layer along the third direction, the second portion is between the first conductive layer and the second isolating layer along the first direction, and the second portion is in contact with the second liner layer along the third direction.

20. The memory system of claim 18, wherein a size of the bottom layer of the contact structure along the first direction at a first position is smaller than a size of the bottom layer of the contact structure along the first direction at a second position, the first position and the second position are arranged along the third direction between the first conductive layer and the contact structure, and the first position is closer to the first conductive layer than the second position along the third direction.
